(19) United States
(12) Patent Application Publication
(10) Pub. No.: US 2017/0293224 A1
(43) Pub. Date: Oct. 12, 2017

(54) ORGANIC EL DISPLAY DEVICE

(71) Applicant: TORAY INDUSTRIES, INC., Tokyo (JP)

(72) Inventors: Satoshi KAMEMOTO, Otsu-shi, Shiga (JP); Takeshi ARAI, Otsu-shi, Shiga (JP); Kazuto MIYOSHI, Otsu-shi, Shiga (JP)

(73) Assignee: TORAY INDUSTRIES, INC., Tokyo (JP)

(21) Appl. No.: 15/507,933

(22) PCT Filed: Sep. 14, 2015
(86) PCT No.: PCT/JP2015/075993

§ 371 Date: Mar. 1, 2017

(30) Foreign Application Priority Data
Sep. 26, 2014 (JP) 2014-196331

(51) Int. Cl. G03F 7/023; H01L 27/32; G03F 7/039

(52) U.S. Cl. CPC G03F 7/0233; G03F 7/039; H01L 27/3258; H01L 27/3262; H01L 27/3276; H01L 2227/323

(57) ABSTRACT

An object of the present invention is to provide an organic EL display device which causes neither decrease in emission luminance nor pixel shrinkage and is excellent in long-term reliability. The present invention is directed to an organic EL display device including an insulating layer formed on a first electrode of the organic EL display device and constituted of a cured film obtained from a positive type photosensitive resin composition containing (A) an alkali-soluble resin, (B) an o-quinonediazide compound and (C) an organic solvent, wherein the mole ratio S/C obtained when a section of the cured film is measured is greater than or equal to 0.003 and less than or equal to 0.008.

### TECHNICAL FIELD

The present invention relates to an organic EL display device provided with an insulating layer formed on a first electrode.

### BACKGROUND ART

An organic EL display device has been attracting attention as a next-generation flat panel display. The organic EL display device is a self-light emitting type display device utilizing electroluminescence emitted from an organic compound, the angle of visibility can be made wide, high speed response can be attained and an image with high contrast can be displayed. Furthermore, since the organic EL display device is characterized as being capable of attaining reduced thickness and reduced weight, in recent years, research and development have been actively conducted.

On the other hand, in the organic EL display device, the long-term reliability is exemplified as one of the problems to be solved. An organic light-emitting material is generally weak against a gas component and moisture, and when being exposed thereto, a decrease in emission luminance and the pixel shrinkage are caused. In this context, the pixel shrinkage refers to a phenomenon of decrease in emission luminance appearing from the end part of a pixel or a phenomenon of lighting failure. For enhancing the long-term reliability of such a display element, not to mention that it is necessary to enhance the durability of the organic light-emitting material itself, it is absolutely necessary to enhance the characteristics of peripheral materials such as a flattening layer which covers a driving circuit and an insulating layer formed on a first electrode. With regard to each of the flattening layer and the insulating layer described above, a desired pattern thereof can be conveniently obtained by using photosensitive resin compositions. Of these, a positive type photosensitive resin composition is preferred in the point of being alkali developable and excellent in resolution characteristics.

Examples of the positive type photosensitive resin composition which has hitherto been proposed include a composition prepared by mixing an o-quinonediazide compound as a photosensitive component with an alkali-soluble resin and using a polyimide precursor as the resin (for example, see Patent Document 1) and a composition prepared by mixing an o-quinonediazide compound as a photosensitive component with an alkali-soluble resin and using a polybenzoxazole precursor as the resin (for example, see Patent Document 2).

### PRIOR ART DOCUMENTS

### Patent Documents

Patent Document 1: Japanese Patent Laid-open Publication No. 2002-91343 (claims 1 to 4)

Patent Document 2: Japanese Patent Laid-open Publication No. 2002-116715 (claims 1 to 4)

### SUMMARY OF THE INVENTION

### Problems to be Solved by the Invention

However, materials proposed in Patent Documents listed above are preferred in the point that an insulating layer can be made to have a normally tapered sectional shape, but it cannot be said that the materials have sufficient performance from the viewpoint of long-term reliability. The present invention has been made in view of the above-mentioned problems and is aimed at providing an organic EL display device which causes neither decrease in emission luminance nor pixel shrinkage and is excellent in long-term reliability.

### Solutions to the Problems

The present invention is directed to an organic EL display device including an insulating layer formed on a first electrode of the organic EL display device and constituted of a cured film obtained from a positive type photosensitive resin composition containing (A) an alkali-soluble resin, (B) ano-quinonediazide compound and (C) an organic solvent, wherein the mole ratio S/C of sulfur to carbon obtained when a section of the cured film is measured by means of an electron probe microanalyzer is greater than or equal to 0.003 and less than or equal to 0.008.

### Effects of the Invention

The organic EL display device according to the present invention can be made into an organic EL display device causing neither decrease in emission luminance nor pixel shrinkage and being excellent in long-term reliability.

### BRIEF DESCRIPTION OF THE DRAWINGS

FIG. 1 is a sectional view of a TFT substrate.

FIG. 2 is a schematic illustration of a substrate for an organic EL display device.

### EMBODIMENTS OF THE INVENTION

The embodiment according to the present invention will be described in detail.

The organic EL display device in accordance with an embodiment of the present invention is an active matrix type organic EL display device having a plurality of pixels formed on a matrix. An active matrix type display device has a TFT (thin film transistor) provided on a substrate made of glass or the like and wirings which are positioned at the lateral side part of the TFT and connected to the TFT, and has a flattening layer which is provided on a driving circuit and covers recesses and protrusions, and furthermore, a display element is provided on the flattening layer. The display element and a wiring are connected through a contact hole formed in the flattening layer. Moreover, in the organic EL display device in accordance with an embodiment of the present invention, an insulating layer is formed on a first electrode.

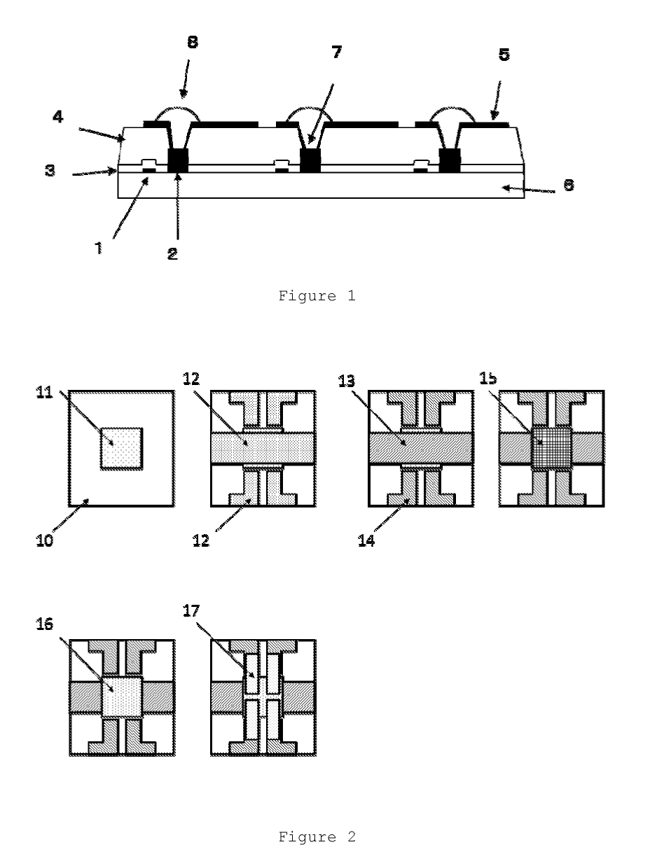

A sectional view of a TFT substrate on which a flattening layer and an insulating layer are formed is shown in FIG. 1. On a substrate 6, bottom gate type or top gate type TFTs 1 are provided in a matrix shape, and a TFT insulating layer 3 in a state of covering the TFTs 1 is formed. Moreover, under the TFT insulating layer 3, a wiring 2 connected to a TFT 1 is provided. Furthermore, on the TFT insulating layer 3, contact holes 7 communicating with the respective wirings 2 and a flattening layer 4 in a state of embedding the space excluding these holes are provided. In the flattening layer 4, openings leading to the respective contact holes 7 of the wirings 2 are provided. And then, an ITO (transparent electrode) 5 in a state of being connected to the wiring 2 through the contact hole 7 is formed on the flattening layer 4. In this context, the ITO 5 constitutes a first electrode of an organic EL element. And then, an insulating layer 8 is formed so as to cover the peripheral edge of the ITO 5. This organic EL element may be a top emission type one which emits emission light from a side opposite to the substrate 6 and may be a bottom emission type one in which light is extracted from the substrate 6 side.

Moreover, one in which organic EL elements having an emission peak wavelength in respective red, green and blue color regions are arranged or one in which white-colored organic EL elements are prepared on the whole face thereof to be used in combination with a separately prepared color filter is called a color display, and usually, peak wavelengths of light displayed in the red color region, green color region and blue color region lie within the ranges of 560 to 700 nm, 500 to 560 nm and 420 to 500 nm, respectively.

A section called a light-emitting pixel section is a portion in which a first electrode and a second electrode, being arranged so as to face each other, are made to cross with each other to be overlapped and is a section in which an insulating layer on the first electrode restricts the range thereof. In an active matrix type display, there are cases where a portion in which a switching means is formed is arranged so as to occupy a part of the light-emitting pixel section, and as the shape of the light-emitting pixel section, a shape formed by the omission of a portion of the section may be adopted instead of a rectangular shape. However, the shape of the light-emitting pixel section is not limited thereto, for example, a circular shape may be adopted, and the shape thereof can be easily modified depending on the shape of an insulating layer.

With regard to the preparation of the organic EL element of the present invention, an organic EL layer is formed by a mask vapor deposition method. The mask vapor deposition method refers to a method of making an organic compound deposit to be subjected to patterning using a vapor deposition mask, and a vapor deposition mask having an opening as a desired pattern is arranged at the vapor deposition source side of a substrate to perform vapor deposition. In order to obtain a vapor deposition pattern with high precision, it is important that a vapor deposition mask having high flatness be brought into close contact with a substrate, and in general, a technique for applying tension to a vapor deposition mask, a technique for bringing a vapor deposition mask into close contact with a substrate by means of a magnet arranged on the back face of the substrate, and the like are used.

Although examples of a manufacturing method of a vapor deposition mask include an etching method, a mechanically polishing method, a sandblasting method, a sintering method, a laser-processing method, a method of using a photosensitive resin, and the like, in the case where a fine pattern is required, there are many cases in which an etching method excellent in processing accuracy or an electroforming method is used.

The constitution of an organic EL layer contained in the organic EL element of the present invention is not particularly limited, and for example, the organic EL layer may be constituted of (1) a hole transport layer/a light-emitting layer, (2) a hole transport layer/a light-emitting layer/an electron transport layer or (3) a light-emitting layer/an electron transport layer.

Subsequently, a second electrode is formed. In an active matrix type one, there are many cases in which a second electrode is solidly formed over the whole light-emitting region. Since the second electrode is required to have a function as a cathode with which electrons can be efficiently injected, in view of the stability of the electrode, there are many cases in which a metallic material is used. In this connection, a first electrode and a second electrode can constitute a cathode and an anode, respectively.

After the second electrode is formed, sealing is performed to obtain an organic EL display device. In general, it is stated that an organic EL element is weak against oxygen and moisture, and in order to obtain a display device high in reliability, it is preferred that sealing be performed under an atmosphere in which amounts of oxygen and moisture are reduced as much as possible. Also with regard to a member used for sealing, it is preferred that a member high in gas barrier properties be selected.

The organic EL display device according to the present invention is characterized as including an insulating layer formed on a first electrode and constituted of a cured film obtained from a positive type photosensitive resin composition containing (A) an alkali-soluble resin, (B) an o-quinonediazide compound and (C) an organic solvent, wherein the mole ratio S/C of sulfur to carbon obtained when a section of the cured film is measured by means of an electron probe microanalyzer is greater than or equal to 0.003 and less than or equal to 0.008.

As a result of extensive researches, the present inventors have ascertained that the sulfur atom contained in the insulating layer is a factor of decreasing the long-term reliability of an organic EL device. More specifically, the present inventors have found that the sulfur component in the flattening layer or the insulating layer oozes out therefrom into the inside of a pixel, and then, a phenomenon of decrease in emission luminance appearing from the end part of the pixel or a phenomenon of lighting failure, which is called pixel shrinkage, is caused.

In view of the problem to be solved, by setting the mole ratio S/C of sulfur to carbon obtained when a section of the cured film is measured by means of an electron probe microanalyzer to be less than or equal to 0.008, more preferably less than or equal to 0.007 and further preferably less than or equal to 0.006, a decrease in emission luminance and the pixel shrinkage do not occur and an organic EL device having sufficient long-term reliability can be obtained. Moreover, by setting the mole ratio S/C to be greater than or equal to 0.003 and more preferably greater than or equal to 0.004, a positive type photosensitive resin having excellent sensitivity can be processed. With regard to the measurement method of the mole ratio S/C of sulfur to carbon, an organic EL display device is disassembled, an insulating layer is exposed by being polished, an electron probe microanalyzer is used, and peak intensities of sulfur and carbon are measured by a quantitative analysis method using a standard sample to be determined.

Moreover, it is preferred that the total amount of gas components derived from the organic solvent among components adsorbed and captured by a purge-and-trap method and detected by gas chromatography-mass spectrometry (GC-MS) in outgassed components emitted when the cured film is heated at 180° C. for 30 minutes be less than or equal to 10 ppm in terms of n-hexadecane. With this setup, the reliability of the organic EL display device can be further enhanced. More specifically, the pixel shrinkage caused due to negligible amounts of the organic solvent remaining in the cured film can be remarkably suppressed. With regard to the measurement method for the outgassed components derived from the organic solvent, an organic EL display device is disassembled, an insulating layer is exposed by being polished, a necessary amount of the insulating layer is collected and then heated for 30 minutes at 180° C., and components adsorbed and captured by a purge-and-trap method are analyzed with GC-MS. As the standard substance, n-hexadecane is adopted and a calibration curve is prepared to determine the amount of gas components generated. In this connection, the gas components derived from the organic solvent refer to compounds specifically described as (C) components mentioned below. Furthermore, it is preferred that the 5% thermal weight reduction temperature of the cured film be higher than or equal to 350° C. With this setup, an effect of further enhancing the long-term reliability of the organic EL display device is attained. With regard to the measurement method of the 5% thermal weight reduction temperature, an organic EL display device is disassembled, an insulating layer is exposed by being polished, a necessary amount of the insulating layer is collected, and then, using a thermogravimetric apparatus, the temperature at a point where the weight is reduced by 5% as compared with the initial weight is measured to be determined.

As in the case of the insulating layer, it is also preferred that the flattening layer formed on a driving circuit be constituted of the above-mentioned cured film. That is, it is preferred that the flattening layer formed on a driving circuit be constituted of a cured film obtained from a positive type photosensitive resin composition containing (A) an alkali-soluble resin, (B) an o-quinonediazide compound and (C) an organic solvent, and the mole ratio S/C of sulfur to carbon obtained when a section of the cured film is measured by means of an electron probe microanalyzer be greater than or equal to 0.003 and less than or equal to 0.008. By using the above-mentioned cured film for the flattening layer, it is possible to further enhance the long-term reliability of the organic EL.

With regard to the cured film constituting the flattening layer, also in the case of measuring the mole ratio S/C of sulfur to carbon, the outgassed components derived from the organic solvent and the 5% thermal weight reduction temperature, an organic EL display device is disassembled, a flattening layer is exposed by being polished, and the measurement is performed in the same manner as that for the insulating layer.

In the organic EL display device according to the present invention, a cured film constituting an insulating layer formed on a first electrode or a cured film constituting a flattening layer formed on a driving circuit is specified as a cured film obtained from a positive type photosensitive resin composition containing (A) an alkali-soluble resin, (B) an o-quinonediazide compound and (C) an organic solvent. That is, the foregoing cured film is specified as a cured film obtained from a specific positive type photosensitive resin composition. Accordingly, there is a possibility that this case is construed as corresponding to “the case in which a claim concerning an invention of a product recites a manufacturing process of the product”.

However, in general, it is difficult to “directly define a cured film based on its structure or characteristics”. Accordingly, it is considered that “any circumstances in which it is utterly impractical to make the applicant define the product (“impossible or impractical circumstances”)” exist.

The positive type photosensitive resin composition used in the present invention contains (A) an alkali-soluble resin. The alkali solubility in the present invention refers to allowing the dissolving speed determined from a reduction in film thickness calculated when a solution prepared by dissolving a resin in γ-butyrolactone is coated on a silicon wafer and is subjected to pre-baking for 4 minutes at 120° C. to form a prebaked film with a film thickness of 10 m±0.5 μm, the prebaked film is immersed in a 2.38% by weight aqueous tetramethylammonium hydroxide solution of 23±1° C. for 1 minute, and then, the film is subjected to a rinse treatment to be greater than or equal to 50 nm/minute.

Examples of the (A) alkali-soluble resin include a polyimide, a polyimide precursor, a polybenzoxazole, a polybenzoxazole precursor, a polyaminoamide, a polyamide, a polymer obtained from radically polymerizable monomers having an alkali-soluble group, a cardo resin, a phenol resin, a cyclic olefin polymer, a siloxane resin, and the like, but the (A) alkali-soluble resin is not limited thereto. The positive type photosensitive resin composition may contain two or more kinds of these resins. Among these alkali-soluble resins, ones being excellent in heat resistance and having a small amount of outgassed components at a high temperature are preferred. Specifically, at least one or more kind of alkali-soluble resin selected among a polyimide, a polyimide precursor and a polybenzoxazole precursor or an interpolymer thereof is preferred.

It is preferred that an alkali-soluble resin selected among a polyimide, a polyimide precursor and a polybenzoxazole precursor or an interpolymer thereof, which can be used as the (A) alkali-soluble resin of the present invention, have an acidic group in a structural unit of the resin and/or at the main-chain terminal for the purpose of imparting the positive type photosensitive resin composition with the alkali solubility. Examples of the acidic group include a carboxyl group, a phenolic hydroxyl group, a sulfonic acid group, and the like, and among these, a carboxyl group or a phenolic hydroxyl group is preferred in the point of not containing a sulfur atom. Moreover, it is preferred that a fluorine atom be contained therein, and at the time of being subjected to development with an alkali aqueous solution, the interface between a film and a base material can be imparted with water repellency to suppress an alkali aqueous solution from permeating the interface. The fluorine atom content in the alkali-soluble resin is preferably greater than or equal to 5% by weight from the viewpoint of the effect of preventing an alkali aqueous solution from permeating the interface, and is preferably less than or equal to 20% by weight from the point of the solubility against an alkali aqueous solution.

The above-described polyimide has a structural unit represented by the following general formula (1), and the polyimide precursor and the polybenzoxazole precursor have a structural unit represented by the following general formula (2). The positive type photosensitive resin composition may contain two or more kinds thereof, and a resin prepared by allowing a structural unit represented by the general formula (1) and a structural unit represented by the general formula (2) to undergo a copolymerization may be used.

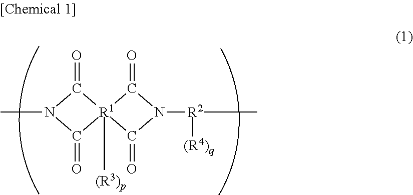

In the general formula (1), R¹ represents a tetra- to decavalent organic group, and R² represents a di- to octavalent organic group. R³ and R⁴ each represent a carboxyl group or a phenolic hydroxyl group, each of R¹ to R⁴ may be constituted of one kind of the group, and different kinds of groups may mixedly coexist in each thereof. In the general formula (1), p and q each represent an integer of 0 to 6.

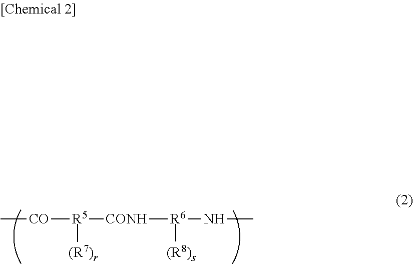

In the general formula (2), R⁵ represents a di- to octavalent organic group, and R⁶ represents a di- to octavalent organic group. R⁷ and R⁸ each represent a phenolic hydroxyl group or COOR⁹, each of R⁵ to R⁸ may be constituted of one kind of the group, and different kinds of groups may mixedly coexist in each thereof. R⁹ represents a hydrogen atom or a monovalent hydrocarbon group with 1 to 20 carbon atoms. In the general formula (2), r and s each represent an integer of 0 to 6. With the proviso that r+s>0.

It is preferred that an alkali-soluble resin selected among a polyimide, a polyimide precursor and a polybenzoxazole precursor or an interpolymer thereof have 5 to 100000 structural units represented by the general formula (1) or (2). Moreover, in addition to the structural unit represented by the general formula (1) or (2), the alkali-soluble resin or the interpolymer may have an additional structural unit. In this case, it is preferred that the alkali-soluble resin or the interpolymer have a structural unit represented by the general formula (1) or (2) in a proportion of greater than or equal to 50% by mole among the total number of structural units.

In the foregoing general formula (1), R¹—(R³)ₚ represents a residue of an acid dianhydride. R¹ represents a tetravalent to decavalent organic group, and of these, an aromatic ring- or cycloaliphatic group-containing organic group with 5 to 40 carbon atoms is preferred.

Specifically, examples of the acid dianhydride include pyromellitic acid dianhydride, 3,3′,4,4′-biphenyltetracarboxylic acid dianhydride, 2,3,3′,4′-biphenyltetracarboxylic acid dianhydride, 2,2′,3,3′-biphenyltetracarboxylic acid dianhydride, 3,3′,4,4′-benzophenonetetracarboxylic acid dianhydride, 2,2′,3,3′-benzophenonetetracarboxylic acid dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)ether dianhydride, 1,2,5,6-naphthalenetetracarboxylic acid dianhydride, 9,9-bis(3,4-dicarboxyphenyl)fluorene dianhydride, 9,9-bis{4-(3,4-dicarboxyphenoxy)phenyl}fluorene dianhydride, 2,3,6,7-naphthalenetetracarboxylic acid dianhydride, 2,3,5,6-pyridinetetracarboxylic acid dianhydride, 3,4,9,10-perylenetetracarboxylic acid dianhydride, 2,2-bis(3,4-dicarboxyphenyl)hexafluoropropane dianhydride, aromatic tetracarboxylic acid dianhydrides such as an acid dianhydride with a structure shown below, aliphatic tetracarboxylic acid dianhydrides such as butanetetracarboxylic acid dianhydride and 1,2,3,4-cyclopentanetetracarboxylic acid dianhydride, and the like. Two or more kinds thereof may be used.

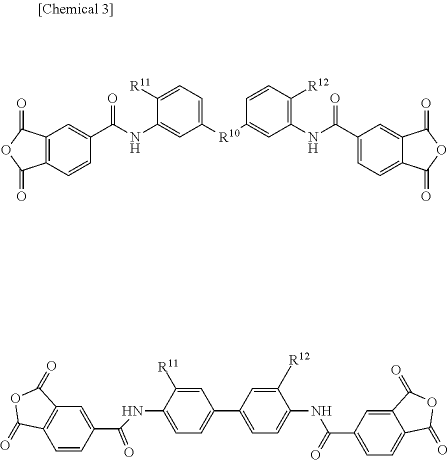

R¹⁰ represents an oxygen atom, C(CF₃)₂ or C(CH₃)₂. R¹¹ and R¹² each represent a hydrogen atom or a hydroxyl group.

In the foregoing general formula (2), R⁵—(R⁷)ᵣ represents a residue of an acid. R⁵ represents a divalent to octavalent organic group, and of these, an aromatic ring- or cycloaliphatic group-containing organic group with 5 to 40 carbon atoms is preferred.

With regard to the acid component, examples of a dicarboxylic acid include terephthalic acid, isophthalic acid, diphenyl ether dicarboxylic acid, bis(carboxyphenyl)hexafluoropropane, biphenyldicarboxylic acid, benzophenone dicarboxylic acid, triphenyldicarboxylic acid, and the like, examples of a tricarboxylic acid include trimellitic acid, trimesic acid, diphenyl ether tricarboxylic acid, biphenyltricarboxylic acid, and the like, and examples of a tetracarboxylic acid include pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2′,3,3′-benzophenonetetracarboxylic acid, 2,2-bis(3,4-dicarboxyphenyl)hexafluoropropane, 2,2-bis(2,3-dicarboxyphenyl)hexafluoropropane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl)ether, 1,2,5,6-naphthalenetetracarboxylic acid, 2,3,6,7-naphthalenetetracarboxylic acid, 2,3,5,6-pyridinetetracarboxylic acid, 3,4,9,10-perylenetetracarboxylic acid, aromatic tetracarboxylic acids with a structure shown below, aliphatic tetracarboxylic acids such as butanetetracarboxylic acid and 1,2,3,4-cyclopentanetetracarboxylic acid, and the like. Two or more kinds thereof may be used.

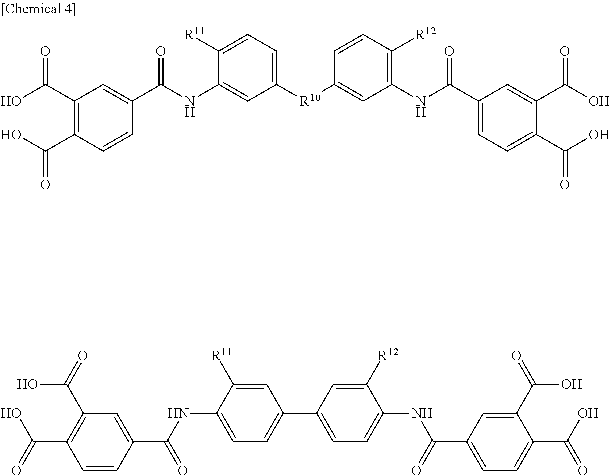

R¹⁰ represents an oxygen atom, C(CF₃)₂ or C(CH₃)₂. R¹¹ and R¹² each represent a hydrogen atom or a hydroxyl group.

Among these, in a tricarboxylic acid or a tetracarboxylic acid, one or two carboxyl group(s) corresponds (correspond) to R⁷ group(s) in the general formula (2). Moreover, preferred is one in which one to four hydrogen atom(s) of the dicarboxylic acid, tricarboxylic acid or tetracarboxylic acid exemplified above is(are) substituted with one to four R⁷ group(s) in the general formula (2), preferably with one to four hydroxyl group(s). These acids can be used directly or converted into acid anhydrides or activated esters to be used.

R²—(R⁴)_{q} in the foregoing general formula (1) and R⁶—(R⁸)ₛ in the foregoing general formula (2) each represent a residue of a diamine. R² and R⁸ each represent a divalent to octavalent organic group, and of these, an aromatic ring- or cycloaliphatic group-containing organic group with 5 to 40 carbon atoms is preferred.

Specific examples of the diamine include 3,4′-diaminodiphenyl ether, 4,4′-diaminodiphenyl ether, 3,4′-diaminodiphenylmethane, 4,4′-diaminodiphenylmethane, 1,4-bis(4-aminophenoxy)benzene, benzidine, m-phenylenediamine, p-phenylenediamine, 1,5-naphthalenediamine, 2,6-naphthalenediamine, bis(4-aminophenoxy)biphenyl, bis{4-(4-aminophenoxy)phenyl}ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-di(trifluoromethyl)-4,4′-diaminobiphenyl, 9,9-bis(4-aminophenyl)fluorene, a compound in which at least some of hydrogen atoms of the aromatic ring thereof are substituted with alkyl groups or halogen atoms, an aliphatic cyclohexyldiamine, methylene biscyclohexylamine, diamines with a structure shown below, and the like. Two or more kinds thereof may be used.

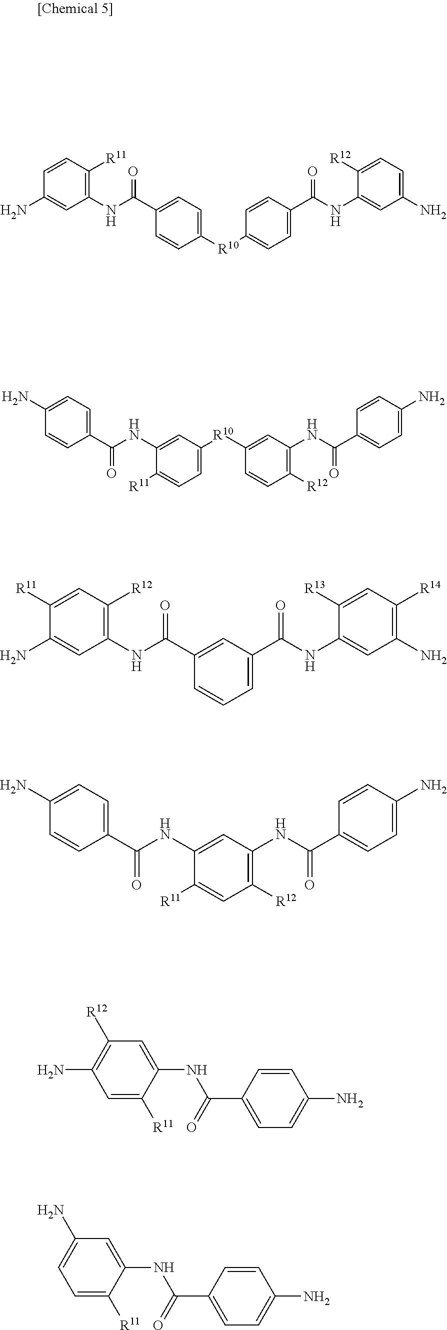

R¹⁰ represents an oxygen atom, C(CF₃)₂ or C(CH₃)₂. R¹¹ to R¹⁴ independently represent a hydrogen atom or a hydroxyl group.

These diamines can be used as diamines or converted into the corresponding diisocyanate compounds or trimethylsilylated diamines to be used.

Moreover, by sealing the terminal of the resin with a monoamine, an acid anhydride, an acid chloride or a monocarboxylic acid which has an acidic group, a resin having an acidic group at the main-chain terminal can be obtained.

Preferred examples of such a monoamine include 5-amino-8-hydroxyquinoline, l-hydroxy-7-aminonaphthalene, 1-hydroxy-6-aminonaphthalene, l-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, l-carboxy-7-aminonaphthalene, l-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 3-amino-4,6-dihydroxypyrimidine, 2-aminophenol, 3-aminophenol, 4-aminophenol, 2-aminothiophenol, 3-aminothiophenol, 4-aminothiophenol, and the like. Two or more kinds thereof may be used.

Preferred examples of such an acid anhydride, an acid chloride or a monocarboxylic acid include acid anhydrides such as phthalic anhydride, maleic anhydride, nadic acid anhydride, cyclohexanedicarboxylic acid anhydride and 3-hydroxyphthalic acid anhydride; a kind of monocarboxylic acid such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene and 1-mercapto-5-carboxynaphthalene and a monoacid chloride compound in which the carboxyl group of the monocarboxylic acid is made into an acid chloride; a monoacid chloride compound in which only one carboxyl group of a kind of dicarboxylic acid such as terephthalic acid, phthalic acid, maleic acid, cyclohexanedicarboxylic acid, 1,5-dicarboxynaphthalene, 1,6-dicarboxynaphthalene, 1,7-dicarboxynaphthalene and 2, 6-dicarboxynaphthalene is made into an acid chloride; and an active ester compound obtained by a reaction between a monoacid chloride compound and N-hydroxybenzotriazole or N-hydroxy-5-norbornene-2,3-dicarboximide. Two or more kinds thereof may be used.

The content of a terminal blocking agent for the above-mentioned monoamine, acid anhydride, acid chloride, monocarboxylic acid or the like is preferably 2 to 25% by mole relative to 100% by mole of the sum of acid and amine components constituting the resin.

The terminal blocking agent introduced into a resin can be easily detected by the following method. For example, by dissolving a resin into which a terminal blocking agent has been introduced in an acidic solution, making the resin decompose into an amine component and an acid component which are constitutional units thereof, and subjecting these components to gas chromatography (GC) or NMR measurement, the terminal blocking agent can be easily detected. Alternatively, by directly subjecting a resin into which a terminal blocking agent has been introduced to pyrolysis gas chromatography (PGC) or the infrared spectrum and ¹³C NMR spectrum measurement, the terminal blocking agent can be detected.

The (A) alkali-soluble resin of the present invention is synthesized by a known method. In the case of a polyamic acid or a polyamic acid ester, with regard to the production method thereof, for example, those can be synthesized by a method of allowing a tetracarboxylic acid dianhydride and a diamine compound to undergo a reaction at a low temperature, a method of preparing a diester from a tetracarboxylic acid dianhydride and an alcohol to be made to react with an amine in the presence of a condensation agent, a method of preparing a diester from a tetracarboxylic acid dianhydride and an alcohol and allowing the residual carboxyl group thereof to be acid chlorinated to be made to react with an amine, and the like.

In the case of a polyhydroxyamide, with regard to the production method thereof, that can be obtained by allowing a bisaminophenol compound and a dicarboxylic acid to undergo a condensation reaction. Specifically, examples of the production method thereof include a method of allowing a dehydration condensation agent such as dicyclohexylcarbodiimide (DCC) and an acid to undergo a reaction and adding a bisaminophenol compound thereto, a method of adding a solution of a dicarboxylic acid dichloride dropwise to a solution of a bisaminophenol compound to which a tertiary amine such as pyridine has been added, and the like.

In the case of a polyimide, that can be obtained by subjecting a polyamic acid or a polyamic acid ester obtained by the above-described method to heating or a chemical treatment with an acid, a base or the like to be dehydrated and cyclized.

With regard to a polymer including radically polymerizable monomers having an alkali-soluble group which can be used as the (A) alkali-soluble resin of the present invention, for the purpose of being imparted with alkali solubility, a radically polymerizable monomer having a phenolic hydroxyl group or a carboxyl group is used. As the radically polymerizable monomer having a phenolic hydroxyl group or a carboxyl group, for example, preferred are o-hydroxystyrene, m-hydroxystyrene and p-hydroxystyrene and an alkyl-, alkoxy-, halogen-, haloalkyl-, nitro-, cyano-, amide-, ester- or carboxy-substituted derivative thereof; a kind of polyhydroxyvinylphenol such as vinylhydroquinone, 5-vinylpyrogallol, 6-vinylpyrogallol and 1-vinylphloroglycinol; o-vinylbenzoic acid, m-vinylbenzoic acid and p-vinylbenzoic acid and an alkyl-, alkoxy-, halogen-, nitro-, cyano-, amide- or ester-substituted derivative thereof; methacrylic acid and acrylic acid and a haloalkyl-, alkoxy-, halogen-, nitro- or cyano-substituted derivative at the α-position thereof; and divalent unsaturated carboxylic acids such as maleic acid, maleic anhydride, fumaric acid, fumaric anhydride, citraconic acid, mesaconic acid, itaconic acid and 1,4-cyclohexenedicarboxylic acid and amethyl-, ethyl-, propyl-, i-propyl-, n-butyl-, sec-butyl-, ter-butyl-, phenyl-, o-toluyl-, m-toluyl- or p-toluyl-half ester and a half amide thereof.

Among these, o-hydroxystyrene, m-hydroxystyrene and p-hydroxystyrene and an alkyl- or alkoxy-substituted derivative thereof are preferably used from the points of the sensitivity or resolution on patterning, the residual film ratio after development, the heat deformation resistance, the solvent resistance, the adhesion to an underlying material, the storage stability of a solution, and the like. One kind thereof can be used and two or more kinds of monomers can be combinedly used.

Moreover, other than these, examples of the radically polymerizable monomer include styrene and an alkyl-, alkoxy-, halogen-, haloalkyl-, nitro-, cyano-, amide- or ester-substituted derivative at the α-position, o-position, m-position or p-position of styrene; a kind of diolefin such as butadiene, isoprene and chloroprene; respective methyl-, ethyl-, n-propyl-, i-propyl-, n-butyl-, sec-butyl-, ter-butyl-, pentyl-, neopentyl-, isoamylhexyl-, cyclohexyl-, adamantyl-, allyl-, propargyl-, phenyl-, naphthyl-, anthracenyl-, anthraquinonyl-, piperonyl-, salicyl-, cyclohexyl-, benzil-, farnesyl-, cresyl-, glycidyl-, 1,1,1-trifluoroethyl-, perfluoroethyl-, perfluoro-n-propyl-, perfluoro-i-propyl-, triphenylmethyl-, tricyclo[5.2.1.0^{2, 6}]decane-8-yl (trivial name: “dicyclopentanyl”)-, cumyl-, 3-(N,N-dimethylamino)propyl-, 3-(N,N-dimethylamino)ethyl-, furyl- and furfuryl-esterified products of methacrylic acid or acrylic acid, and an anilide or an amide of methacrylic acid or acrylic acid, and moreover, N,N-dimethyl, N,N-diethyl, N,N-dipropyl, N,N-diisopropyl, anthranilamide, acrylonitrile, acrolein, methacrylonitrile, vinyl chloride, vinylidene chloride, vinyl fluoride, vinylidene fluoride, N-vinylpyrrolidone, vinylpyridine, vinyl acetate, N-phenylmaleinimide, N-(4-hydroxyphenyl)maleinimide, N-methacryloylphthalimide, N-acryloylphthalimide, and the like can be used. One kind thereof can be used and two or more kinds thereof can be combinedly used.

Among these, styrene and an alkyl-, alkoxy-, halogen- or haloalkyl-substituted derivative at the α-position, o-position, m-position or p-position of styrene; butadiene, isoprene; respective methyl-, ethyl-, n-propyl-, n-butyl-, glycidyl- and tricyclo[5.2.1.0^{2, 6}]decane-8-yl-esterified products of methacrylic acid or acrylic acid are especially suitably used from the points of the sensitivity or resolution on patterning, the residual film ratio after development, the heat deformation resistance, the solvent resistance, the adhesion to an underlying material, the storage stability of a solution. In the case of using a copolymer of a radically polymerizable monomer having a phenolic hydroxyl group and another radically polymerizable monomer as the alkali-soluble resin, the preferred proportion of another radically polymerizable monomer is preferably less than or equal to 40% by weight and especially preferably 5 to 30% by weight relative to the total amount of the radically polymerizable monomer having a phenolic hydroxyl group and another radically polymerizable monomer. Moreover, in the case of using a copolymer of a radically polymerizable monomer having a carboxyl group and another radically polymerizable monomer as the alkali-soluble resin, the preferred proportion of another radically polymerizable monomer is preferably less than or equal to 90% by weight and especially preferably 10 to 80% by weight relative to the total amount of the radically polymerizable monomer having a carboxyl group and another radically polymerizable monomer. When the proportion of each of these radically polymerizable monomers to the radically polymerizable monomer having a phenolic hydroxyl or a carboxyl group is greater than the above-described upper limit, there are cases where it becomes difficult to perform alkali development.

Examples of a solvent used in the production of a polymer including a radically polymerizable monomer having an alkali-soluble group include a kind of alcohol such as methanol and ethanol; a kind of ether such as tetrahydrofuran; a kind of glycol ether such as ethylene glycol monomethyl ether and ethylene glycol monoethyl ether; a kind of ethylene glycol alkyl ether acetate such as methyl cellosolve acetate and ethyl cellosolve acetate; a kind of diethylene glycol such as diethylene glycol monomethyl ether, diethylene glycol monoethyl ether, diethylene glycol dimethyl ether, diethylene glycol diethyl ether and diethylene glycol ethyl methyl ether; a kind of propylene glycol monoalkyl ether such as propylene glycol monomethyl ether, propylene glycol monoethyl ether, propylene glycol monopropyl ether and propylene glycol monobutyl ether; a kind of propylene glycol alkyl ether acetate such as propylene glycol methyl ether acetate, propylene glycol ethyl ether acetate, propylene glycol propyl ether acetate and propylene glycol butyl ether acetate; a kind of propylene glycol alkyl ether propionate such as propylene glycol methyl ether propionate, propylene glycol ethyl ether propionate, propylene glycol propyl ether propionate and propylene glycol butyl ether propionate; a kind of aromatic hydrocarbon such as toluene and xylene; a kind of ketone such as methyl ethyl ketone, cyclohexanone and 4-hydroxy-4-methyl-2-pentanone; and a kind of ester such as methyl acetate, ethyl acetate, propyl acetate, butyl acetate, 2-hydroxypropionic acid ethyl ester, 2-hydroxy-2-methylpropionic acid methyl ester, 2-hydroxy-2-methylpropionic acid ethyl ester, hydroxyacetic acid methyl ester, hydroxyacetic acid ethyl ester, hydroxyacetic acid butyl ester, methyl lactate, ethyl lactate, propyl lactate, butyl lactate, 3-hydroxypropionic acid methyl ester, 3-hydroxypropionic acid ethyl ester, 3-hydroxypropionic acid propyl ester, 3-hydroxypropionic acid butyl ester, 2-hydroxy-3-methylbutanoic acid methyl ester, methoxyacetic acid methyl ester, methoxyacetic acid ethyl ester, methoxyacetic acid propyl ester, methoxyacetic acid butyl ester, ethoxyacetic acid methyl ester, ethoxyacetic acid ethyl ester, ethoxyacetic acid propyl ester, ethoxyacetic acid butyl ester, propoxyacetic acid methyl ester, propoxyacetic acid ethyl ester, propoxyacetic acid propyl ester, propoxyacetic acid butyl ester, butoxyacetic acid methyl ester, butoxyacetic acid ethyl ester, butoxyacetic acid propyl ester, butoxyacetic acid butyl ester, 2-methoxypropionic acid methyl ester, 2-methoxypropionic acid ethyl ester, 2-methoxypropionic acid propyl ester, 2-methoxypropionic acid butyl ester, 2-ethoxypropionic acid methyl ester, 2-ethoxypropionic acid ethyl ester, 2-ethoxypropionic acid propyl ester, 2-ethoxypropionic acid butyl ester, 2-butoxypropionic acid methyl ester, 2-butoxypropionic acid ethyl ester, 2-butoxypropionic acid propyl ester, 2-butoxypropionic acid butyl ester, 3-methoxypropionic acid methyl ester, 3-methoxypropionic acid ethyl ester, 3-methoxypropionic acid propyl ester, 3-methoxypropionic acid butyl ester, 3-ethoxypropionic acid methyl ester, 3-ethoxypropionic acid ethyl ester, 3-ethoxypropionic acid propyl ester, 3-ethoxypropionic acid butyl ester, 3-propoxypropionic acid methyl ester, 3-propoxypropionic acid ethyl ester, 3-propoxypropionic acid propyl ester, 3-propoxypropionic acid butyl ester, 3-butoxypropionic acid methyl ester, 3-butoxypropionic acid ethyl ester, 3-butoxypropionic acid propyl ester and 3-butoxypropionic acid butyl ester. The amount of the solvent used is preferably 20 to 1000 parts by weight per 100 parts by weight of the radically polymerizable monomer.

Examples of a polymerization initiator used in the production of a polymer including a radically polymerizable monomer having an alkali-soluble group include azo compounds such as 2,2′-azobisisobutyronitrile, 2,2′-azobis-(2,4-dimethylvaleronitrile) and 2,2′-azobis-(4-methoxy-2,4-dimethylvaleronitrile); organic peroxides such as benzoyl peroxide, lauroyl peroxide, t-butylperoxypivalate and 1,1′-bis-(t-butylperoxy)cyclohexane; and hydrogen peroxide. In the case of using a peroxide as a radical polymerization initiator, the peroxide may be used together with a reducing agent to form a redox type initiator.

The preferred weight average molecular weight of a polymer including a radically polymerizable monomer having an alkali-soluble group is preferably 2000 to 100000, more preferably 3000 to 50000 and especially preferably 5000 to 30000 in terms of polystyrene measured by gel permeation chromatography. When the weight average molecular weight is greater than 100000, there is a tendency for the developability and sensitivity to deteriorate, and when being less than 2000, the pattern shape, resolution, developability and heat resistance are liable to become poor.

One kind of these polymers including a radically polymerizable monomer having an alkali-soluble group may be used alone, and two or more kinds thereof may be mixedly used. Moreover, an alkali-soluble resin may be synthesized by a method of imparting the resin with alkali solubility by introducing a protecting group into the carboxyl group or the phenolic hydroxyl group before polymerization to eliminate the protecting group after polymerization. Furthermore, the resin may be made to vary in the transparency for visible light or the softening point by being subjected to a hydrogenation treatment and the like.

Examples of the cardo resin used as the (A) alkali-soluble resin of the present invention include a resin having a cardo structure, namely, a skeletal structure making two cyclic structural parts bond to a quaternary carbon atom constituting a cyclic structural part. As a common example of the cardo structure, the structure making a benzene ring bond to a fluorene ring is exemplified.

Specific examples of the skeletal structure making two cyclic structural parts bond to a quaternary carbon atom constituting a cyclic structural part include a fluorene skeleton, a bisphenolfluorene skeleton, bisaminophenyl fluorene skeleton, a fluorene skeleton with an epoxy group, a fluorene skeleton with an acrylic group, and the like.

The cardo resin is formed by allowing monomers to undergo a polymerization utilizing a reaction between functional groups of the monomers to each of which a skeleton having the cardo structure is made to bond, and the like. The cardo resin has a structure (cardo structure) in which a main chain and a bulky side chain are connected through an element, and has a cyclic structural part along the direction almost perpendicular to a plane including the main chain.

Specific examples of the monomer having a cardo structure include a kind of cardo structure-containing bisphenol such as a bis(glycidyloxyphenyl)fluorene type epoxy resin, 9,9-bis(4-hydroxyphenyl)fluorene and 9,9-bis (4-hydroxy-3-methylphenyl)fluorene, a kind of 9,9-bis(cyanoalkyl)fluorene such as 9,9-bis(cyanomethyl)fluorene, a kind of 9,9-bis(aminoalkyl)fluorene such as 9,9-bis(3-aminopropyl)fluorene, and the like.

The cardo resin is a polymer obtained by allowing monomers having a cardo structure to undergo a polymerization, but the cardo resin may be an interpolymer of a monomer having a cardo structure and another copolymerizable monomer.

As the polymerization method of the monomers, a general method can be used, and examples thereof include a ring-opening polymerization method, an addition polymerization method, and the like.

Examples of the phenol resin used as the (A) alkali-soluble resin of the present invention include a novolak phenol resin and a resol phenol resin, and those are obtained by allowing one kind of various kinds of phenol or a mixture of plural kinds thereof and a kind of aldehyde such as formalin to undergo a polycondensation.

Examples of a kind of phenol constituting the novolak phenol resin or the resol phenol resin include phenol, p-cresol, m-cresol, o-cresol, 2,3-dimethylphenol, 2,4-dimethylphenol, 2,5-dimethylphenol, 2,6-dimethylphenol, 3,4-dimethylphenol, 3,5-dimethylphenol, 2,3,4-trimethylphenol, 2,3,5-trimethylphenol, 3,4,5-trimethylphenol, 2,4,5-trimethylphenol, methylenebisphenol, methylenebis p-cresol, resorcin, catechol, 2-methylresorcin, 4-methylresorcin, o-chlorophenol, m-chlorophenol, p-chlorophenol, 2,3-dichlorophenol, m-methoxyphenol, p-methoxyphenol, p-butoxyphenol, o-ethylphenol, m-ethylphenol, p-ethylphenol, 2,3-diethylphenol, 2,5-diethylphenol, p-isopropylphenol, α-naphthol, 1-naphthol, and the like, and these can be used alone or as a mixture of plural kinds thereof.

Moreover, in addition to formalin, examples of a kind of aldehyde include paraformaldehyde, acetaldehyde, benzaldehyde, hydroxybenzaldehyde, chloroacetaldehyde, and the like, and these can be used alone or as a mixture of plural kinds thereof.

It is preferred that the preferred weight average molecular weight of the phenol resin used in the present invention lie within the range of 2000 to 50000, preferably 3000 to 30000, in terms of polystyrene measured by gel permeation chromatography. When the weight average molecular weight is greater than 50000, there is a tendency for the developability and sensitivity to deteriorate, and when being less than 2000, the pattern shape, resolution, developability and heat resistance are liable to become poor.

Examples of the cyclic olefin polymer used as the (A) alkali-soluble resin of the present invention include a single polymer of a cyclic olefin monomer having a cyclic structure (alicyclic structure or aromatic ring) and a carbon-carbon double bond or an interpolymer of plural kinds of cyclic olefin monomers. The cyclic olefin polymer may include a monomer other than the cyclic olefin monomer.

Examples of the monomer for constituting the cyclic olefin polymer include a cyclic olefin monomer having a protic polar group, a cyclic olefin monomer having a polar group other than the protic polar group, a cyclic olefin monomer having no polar group, a monomer other than the cyclic olefin monomer, and the like. In this connection, a monomer other than the cyclic olefin monomer may have a protic polar group or a polar group other than this, and may have no polar group.

Specific examples of the cyclic olefin monomer having a protic polar group include carboxyl group-containing cyclic olefins such as 5-hydroxycarbonylbicyclo[2.2.1]hept-2-ene, 5-methyl-5-hydroxycarbonylbicyclo[2.2.1]hept-2-ene, 5-carboxymethyl-5-hydroxycarbonylbicyclo[2.2.1]hept-2-ene, 5-exo-6-endo-dihydroxycarbonylbicyclo[2.2.1]hept-2-ene, 8-hydroxycarbonyltetracyclo[4.4.0.1^{2,5}.1^{7,10}]dodeca-3-ene, 8-methyl-8-hydroxycarbonyltetracyclo[4.4.0.1^{2,5}.1⁷, o]dodeca-3-ene and 8-exo-9-endo-dihydroxycarbonyltetracyclo[4.4.0.1^{2,5}.1^{7,10}]dodeca-3-ene; hydroxyl group-containing cyclic olefins such as 5-(4-hydroxyphenyl)bicyclo[2.2.1]hept-2-ene, 5-methyl-5-(4-hydroxyphenyl)bicyclo[2.2.1]hept-2-ene, 8-(4-hydroxyphenyl)tetracyclo[4.4.0.1^{2,5}.1^{7,10}]dodeca-3-ene and 8-methyl-8-(4-hydroxyphenyl)tetracyclo[4.4.0.1^{2,5}.1^{7,10}]dodeca-3-ene, and the like. One kind of these monomers may be used alone, and two or more kinds thereof may be used in combination.

Specific examples of the cyclic olefin monomer having a polar group other than the protic polar group include cyclic olefins having an ester group such as 5-acetoxybicyclo[2.2.1]hept-2-ene, 5-methoxycarbonylbicyclo[2.2.1]hept-2-ene, 5-methyl-5-methoxycarbonylbicyclo[2.2.1]hept-2-ene, 8-acetoxytetracyclo[4.4.0.1^{2,5}.1^{7,10}]dodeca-3-ene, 8-methoxycarbonyltetracyclo[4.4.0.1^{2,5}.1^{7,10}]dodeca-3-ene, 8-ethoxycarbonyltetracyclo[4.4.0.1^{2,5}.1^{7,10}]dodeca-3-ene, 8-n-propoxycarbonyltetracyclo[4.4.0.1^{2,5}.1^{7,10}]dodeca-3-ene, 8-isopropoxycarbonyltetracyclo[4.4.0.1^{2,5}.1^{7,10}]dodeca-3-ene, 8-n-butoxycarbonyltetracyclo[4.4.0.1^{2,5}.1^{7,10}]dodeca-3-ene, 8-methyl-8-methoxycarbonyltetracyclo[4.4.0.1^{2,5}.1^{7,10}]dodeca-3-ene, 8-methyl-8-ethoxycarbonyltetracyclo[4.4.0.1^{2,5}.1^{7,10}]dodeca-3-ene, 8-methyl-8-n-propoxycarbonyltetracyclo[4.4.0.1^{2,5}.1^{7,10}]dodeca-3-ene, 8-methyl-8-isopropoxycarbonyltetracyclo[4.4.0.1^{2,5}.1^{7,10} ]dodeca-3-ene, 8-methyl-8-n-butoxycarbonyltetracyclo[4.4.0.1^{2,5}.1^{7,10}]dodeca-3-ene, 8-(2,2,2-trifluoroethoxycarbonyl)tetracyclo[4.4.0.1^{2,5}.1^{7,10}]dodeca-3-ene and 8-methyl-8-(2,2,2-trifluoroethoxycarbonyl)tetracyclo[4.4.0.1^{2,5}.1^{7,10}]dodeca-3-ene; cyclic olefins having an N-substituted imide group such as N-phenyl-(5-norbornene-2,3-dicarboximide); cyclic olefins having a cyano group such as 8-cyanotetracyclo[4.4.0.1^{2,5}.1^{7,10}]dodeca-3-ene, 8-methyl-8-cyanotetracyclo[4.4.0.1^{2,5}.1^{7,10}]dodeca-3-ene and 5-cyanobicyclo[2.2.1]hept-2-ene; and cyclic olefins having a halogen atom such as 8-chlorotetracyclo[4.4.0.1^{2,5}.1^{7,10}]dodeca-3-ene and 8-methyl-8-chlorotetracyclo[4.4.0.1^{2,5}.1^{7,10}]dodeca-3-ene. One kind of these monomers may be used alone, and two or more kinds thereof may be used in combination.

Specific examples of the cyclic olefin monomer having no polar group include bicyclo[2.2.1]hept-2-ene, 5-ethyl-bicyclo[2.2.1]hept-2-ene, 5-butyl-bicyclo[2.2.1]hept-2-ene, 5-ethylidene-bicyclo[2.2.1]hept-2-ene, 5-methylidene-bicyclo[2.2.1]hept-2-ene, 5-vinyl-bicyclo[2.2.1]hept-2-ene, tricyclo[4.3.0.1^{2,5} ]deca-3,7-diene, tetracyclo[8.4.0.1^{11,14}.0^{3,7} ]pentadeca-3,5,7,12,11-pentaene, tetracyclo[4.4.0.1^{2,5}.1^{7,10}]deca-3-ene, 8-methyl-tetracyclo[4.4.0.1^{2,5}.1^{7,10}]dodeca-3-ene, 8-ethyl-tetracyclo[4.4.0.1^{2,5}.1^{7,10}]dodeca-3-ene, 8-methylidene-tetracyclo[4.4.0.1^{2,5}.1^{7,10}]dodeca-3-ene, 8-ethylidene-tetracyclo[4.4.0.1^{2,5}.1^{7,10}]dodeca-3-ene, 8-vinyl-tetracyclo[4.4.0.1^{2,5}.1^{7,10}]dodeca-3-ene, 8-propenyl-tetracyclo[4.4.0.1^{2,5}.1^{7,10}]dodeca-3-ene, pentacyclo[6.5.1.1^{3,6}.0^{2,7}.0^{9,13} ]pentadeca-3,10-diene, cyclopentene, cyclopentadiene, 1,4-methano-1,4,4a,5,10,10α-hexahydroanthracene, 8-phenyl-tetracyclo[4.4.0.1^{2,5}.1^{7,10}]dodeca-3-ene, tetracyclo[9.2.1.0^{2,10}.0^{3,8}]tetradeca-3,5,7,12-tetraene, pentacyclo[7.4.0.1^{3,6}.1^{10,13}.0^{2,7}]pentadeca-4,11-diene, pentacyclo[9.2.1.1^{4,7}.0^{2,10}.0^{3,8}]pentadeca-5,12-diene, and the like. One kind of these monomers may be used alone, and two or more kinds thereof may be used in combination.

Specific examples of the monomer other than the cyclic olefin monomer include linear olefins including ethylene; α-olefins with 2 to 20 carbon atoms such as propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene and 1-eicosene; nonconjugated dienes such as 1,4-hexadiene, 4-methyl-1,4-hexadiene, 5-methyl-1,4-hexadiene and 1,7-octadiene, and the like. One kind of these monomers may be used alone, and two or more kinds thereof may be used in combination.

As a method for polymerizing the monomer to prepare a cyclic olefin polymer, a general method can be used. Examples thereof include a ring-opening polymerization method, an addition polymerization method, and the like.

On this occasion, as a polymerization catalyst used, for example, a metal complex containing molybdenum, ruthenium, osmium or the like is suitably used. One kind of these polymerization catalysts can be used alone or two or more kinds thereof can be used in combination.

With regard to a cyclic olefin polymer obtained by allowing respective kinds of monomers to undergo a polymerization, the hydrogenation is usually performed with a hydrogenation catalyst. As the hydrogenation catalyst, for example, a catalyst which is generally used at the time of the hydrogenation for an olefin compound can be used. Specifically, a Ziegler type homogeneous catalyst, a noble metal complex catalyst, a supported type noble metal-based catalyst, and the like can be utilized.

Among these hydrogenation catalysts, from the points of causing no side reaction making a functional group suffer denaturation or the like and enabling carbon-carbon unsaturated bonds in the polymer to be selectively hydrogenated, a noble metal complex catalyst containing rhodium, ruthenium or the like is preferred, and a nitrogen-containing heterocyclic carbene compound high in electro-donicity or a ruthenium catalyst coordinated with a kind of phosphine is especially preferred.

Examples of the siloxane resin used as the (A) alkali-soluble resin of the present invention include a polysiloxane obtained by allowing at least one kind of compound selected from an organosilane represented by the general formula (3) and an organosilane represented by the general formula (4) to undergo hydrolysis condensation. By using an organosilane represented by the general formula (3) or (4), a photosensitive colored resin composition excellent in sensitivity and resolution can be obtained.

The organosilane represented by the general formula (3), which is used in the present invention, is as follows.

[Chemical 6]

(R¹⁵)ₘSi(OR¹⁶)₄₋ₘ (3)

(In the foregoing general formula (3), R¹⁵ represents a hydrogen atom, an alkyl group with 1 to 10 carbon atom(s), an alkenyl group with 2 to 10 carbon atoms or an aryl group with 6 to 16 carbon atoms. R¹⁶ represents a hydrogen atom, an alkyl group with 1 to 6 carbon atom(s), an acyl group with 2 to 6 carbon atoms or an aryl group with 6 to 16 carbon atoms. m represents an integer of 0 to 3. In the case where m is greater than or equal to 2, plural R¹⁵s may be the same as or different from one another. Moreover, In the case where m is less than or equal to 2, plural R¹⁶s may be the same as or different from one another.)

Specific examples of the organosilane represented by the general formula (3) include tetrafunctional silanes such as tetramethoxysilane, tetraethoxysilane, tetraacetoxysilane and tetraphenoxysilane; trifunctional silanes such as methyltrimethoxysilane, methyltriethoxysilane, methyltriisopropoxysilane, methyltri n-butoxysilane, ethyltrimethoxysilane, ethyltriethoxysilane, ethyltriisopropoxysilane, ethyltri n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, phenyltrimethoxysilane, phenyltriethoxysilane, p-hydroxyphenyltriethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, 3-trimethoxysilylpropyl succinic acid, 1-naphthyltrimethoxysilane, 1-naphthyltriethoxysilane, 1-naphthyltri-n-propoxysilane, 2-naphthyltrimethoxysilane, 1-anthracenyltrimethoxysilane, 9-anthracenyltrimethoxysilane, 9-phenanthrenyltrimethoxysilane, 9-fluorenyltrimethoxysilane, 2-fluorenyltrimethoxysilane, 1-pyrenyltrimethoxysilane, 2-indenyltrimethoxysilane and 5-acenaphthenyltrimethoxysilane; bifunctional silanes such as dimethyldimethoxysilane, dimethyldiethoxysilane, dimethyldiacetoxysilane, di n-butyldimethoxysilane, diphenyldimethoxysilane, (3-glycidoxypropyl)methyldimethoxysilane, (3-glycidoxypropyl)methyldiethoxysilane, di(1-naphthyl)dimethoxysilane and di (1-naphthyl) diethoxysilane; and monofunctional silanes such as trimethylmethoxysilane, tri n-butylethoxysilane, (3-glycidoxypropyl)dimethylmethoxysilane and (3-glycidoxypropyl)dimethylethoxysilane. Two or more kinds of these organosilanes may be used. The organosilane represented by the general formula (4), which is used in the present invention, is as follows.

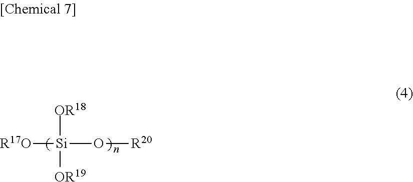

(In the foregoing general formula (4), R¹⁷ to R²⁰ independently represent a hydrogen atom, an alkyl group with 1 to 6 carbon atom(s), an acyl group with 2 to 6 carbon atoms or an aryl group with 6 to 16 carbon atoms. n represents an integer lying within the range of 2 to 8. In the case where n is greater than or equal to 2, plural R¹⁸s and R¹⁹s may be the same as or different from one another.)

Specific examples of the organosilane represented by the general formula (4) include Methyl Silicate 51 (R¹⁷ to R²⁰: methyl group, n: average 4) available from FUSO CHEMICAL CO., LTD., M Silicate 51 (R¹⁷ to R²⁰: methyl group, n: average 3 to 5), Silicate 40 (R¹⁷ to R²⁰: ethyl group, n: average 4 to 6) and Silicate 45 (R¹⁷ to R²⁰: ethyl group, n: average 6 to 8) available from TAMA CHEMICALS CO., LTD., Methyl Silicate 51 (R¹⁷ to R²⁰: methyl group, n: average 4), Methyl Silicate 53A (R¹⁷ to R²⁰ methyl group, n: average 7) and Ethyl Silicate 40 (R¹⁷ to R²⁰: ethyl group, n: average 5) available from COLCOAT CO., LTD., and the like, and these are obtainable from the respective companies. Two or more kinds thereof may be used.

The content of the Si atom derived from the organosilane represented by the general formula (3) or (4) in a polysiloxane can be determined by specifying the structure of the organosilane constituting the raw material by means of ¹H-NMR, ¹³C-NMR, ²⁹Si-NMR, IR, TOF-MS and the like to calculate the integration ratio of a peak derived from Si—C bond to a peak derived from Si—O bond in the IR spectrum.

Although the weight average molecular weight (Mw) of the polysiloxane is not particularly limited, when being greater than or equal to 1,000 in terms of polystyrene measured by GPC (gel permeation chromatography), the weight average molecular weight is preferred because the coated film-forming properties are enhanced. On the other hand, from the viewpoint of the solubility against a developing solution, the weight average molecular weight is preferably less than or equal to 100,000 and more preferably less than or equal to 50,000.

The polysiloxane in the present invention is synthesized by allowing monomers such as organosilanes represented by the general formula (3) and (4) to undergo hydrolysis and partial condensation. In this context, undergoing partial condensation refers to making some of Si—OH bonds remain in the resulting polysiloxane without allowing all of the Si—OH bonds of a hydrolyzate to undergo condensation. For the hydrolysis and partial condensation, a general method can be used. Examples thereof include a method of adding a solvent and water, optionally together with a catalyst, to a mixture of organosilanes and allowing the contents to be heated and stirred for 0.5 to 100 hour(s) or so at 50 to 150° C., and the like. During the stirring operation, hydrolysis by-products (alcohol such as methanol) and condensation by-products (water) may be distilled off by distillation, as necessary.

Although no particular restriction is put on the catalyst, an acid catalyst or a base catalyst is preferably used. Specific examples of the acid catalyst include hydrochloric acid, nitric acid, sulfuric acid, hydrofluoric acid, phosphoric acid, acetic acid, trifluoroacetic acid, formic acid, a polycarboxylic acid or an anhydride thereof, an ion exchange resin, and the like. Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, an alkoxysilane having an amino group, an ion exchange resin, and the like.

Moreover, from the viewpoint of storage stability of the positive type photosensitive resin composition, it is preferred that the catalyst not be contained in a polysiloxane solution after hydrolysis and partial condensation, and removal of the catalyst can be performed as necessary. Although no particular restriction is put on the removal method, in the points of simplicity of operation and removability, water washing and/or a treatment by an ion exchange resin are/is preferred. The water washing refers to a method of diluting a polysiloxane solution with a proper hydrophobic solvent, washing the diluted liquid several times with water and then concentrating the resulting organic layer by means of an evaporator or the like. The treatment by an ion exchange resin refers to a method of bringing a polysiloxane solution into contact with a proper ion exchange resin.

The positive type photosensitive resin composition used in the present invention contains (B) an o-quinonediazide compound. As the o-quinonediazide compound, a compound making the sulfonic acid moiety of naphthoquinonediazide sulfonate bond to a compound having a phenolic hydroxyl group through the ester moiety is preferred. As the compound having a phenolic hydroxyl group used herein, a compound prepared by introducing naphthoquinonediazide-4-sulfonate or naphthoquinonediazide-5-sulfonate into a compound such as Bis-Z, BisP-EZ, TekP-4HBPA, TrisP-HAP, TrisP-PA, TrisP-SA, TrisOCR-PA, BisOCHP-Z, BisP-MZ, BisP-PZ, BisP-IPZ, BisOCP-IPZ, BisP-CP, BisRS-2P, BisRS-3P, BisP-OCHP, Methylene tris-FR-CR, BisRS-26X, DML-MBPC, DML-MBOC, DML-OCHP, DML-PCHP, DML-PC, DML-PTBP, DML-34X, DML-EP, DML-POP, Dimethylol-BisOC-P, DML-PFP, DML-PSBP, DML-MTrisPC, TriML-P, TriML-35XL, TML-BP, TML-HQ, TML-pp-BPF, TML-BPA, TMOM-BP, HML-TPPHBA, HML-TPHAP (trade names, available from Honshu Chemical Industry Co., Ltd.), BIR-OC, BIP-PC, BIR-PC, BIR-PTBP, BIR-PCHP, BIP-BIOC-F, 4PC, BIR-BIPC-F, TEP-BIP-A, 46DMOC, 46DMOEP, TM-BIP-A (trade names, available from ASAHI YUKIZAI CORPORATION), 2,6-dimethoxymethyl-4-tert-butylphenol, 2,6-dimethoxymethyl-p-cresol, 2,6-diacetoxymethyl-p-cresol, naphthol, tetrahydroxybenzophenone, gallic acid methyl ester, bisphenol A, bisphenol E, methylenebisphenol and BisP-AP (trade names, available from Honshu Chemical Industry Co., Ltd.) through the ester bond can be preferably exemplified, but a compound other than this can be used.

The 4-naphthoquinonediazide sulphonyl ester compound has an absorption in the i-line region of a mercury lamp and is suitable for i-line exposure, and the 5-naphthoquinonediazide sulphonyl ester compound has an absorption extending up to the g-line region of a mercury lamp and is suitable for g-line exposure. In the present invention, both of the 4-naphthoquinonediazide sulphonyl ester compound and the 5-naphthoquinonediazide sulphonyl ester compound can be preferably used, but it is preferred that the 4-naphthoquinonediazide sulphonyl ester compound or the 5-naphthoquinonediazide sulphonyl ester compound be selected depending on the wavelength of light used for the exposure. Moreover, a naphthoquinonediazide sulphonyl ester compound in which a 4-naphthoquinonediazide sulphonyl group and a 5-naphthoquinonediazide sulphonyl group are combinedly used in the identical molecule can also be obtained, and the 4-naphthoquinonediazide sulphonyl ester compound and the 5-naphthoquinonediazide sulphonyl ester compound can be mixedly used.

Among these, with regard to the 4-naphthoquinonediazide sulphonyl ester compound, since an o-quinonediazide compound is decomposed in the heating treatment process and a part thereof is converted into sulfur dioxide to be eliminated to the outside of the film, the amount of sulfur atoms contained in the cured film can be reduced. As a result, the compound is especially preferably used because pixel shrinkage derived from the sulfur atom can be further suppressed.

The naphthoquinonediazide compound can be synthesized by the esterification reaction of a compound having a phenolic hydroxyl group and a naphthoquinonediazide sulfonate compound, and can be synthesized by a known method. By using these naphthoquinonediazide compounds, the resolution, the sensitivity and the residual film ratio are further enhanced.

The addition amount of the (B) component is preferably greater than or equal to 4% by weight, more preferably greater than or equal to 5% by weight, further preferably greater than or equal to 6% by weight, preferably less than or equal to 12% by weight, more preferably less than or equal to 10% by weight and further preferably less than or equal to 9% by weight, relative to the whole amount of the resin composition excluding the solvent. By setting the amount to be greater than or equal to 4% by weight, a pattern excellent in sensitivity can be formed, and by setting the amount to be less than or equal to 12% by weight, pixel shrinkage derived from the sulfur atom of the o-quinonediazide compound can be suppressed and long-term reliability of the organic EL device can be enhanced.

The positive type photosensitive resin composition used in the present invention contains (C) an organic solvent. This enables the resin composition to be in the condition of being a varnish and enables the coating properties to be enhanced.

Examples of the organic solvent include a polar aprotic solvent such as γ-butyrolactone; a kind of ether such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether, tetrahydrofuran and dioxane; a kind of ketone such as acetone, methyl ethyl ketone, diisobutyl ketone, cyclohexanone, 2-heptanone, 3-heptanone and diacetone alcohol; a first kind of ester such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate and ethyl lactate; a second kind of ester such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butylpropionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate and ethyl 2-oxobutanoate; a kind of aromatic hydrocarbon such as toluene and xylene; a kind of amide such as N-methylpyrrolidone, N,N-dimethylformamide and N,N-dimethylacetamide, and the like, and these solvents can be used singly or mixedly.

Although the amount of the organic solvent used is not particularly limited, the amount of the organic solvent used is preferably 100 to 3000% by weight and further preferably 150 to 2000 parts by weight, relative to the whole amount of the resin composition excluding the solvent. Moreover, the proportion of a solvent with a boiling point higher than or equal to 180° C. to the whole amount of the organic solvent is preferably less than or equal to 20% by weight and further preferably less than or equal to 10% by weight. By setting the proportion of a solvent with a boiling point higher than or equal to 180° C. to be less than or equal to 30% by weight, the amount of the outgassed component from the thermally cured flattening layer or insulating layer can be suppressed low, and as a result, long-term reliability of the organic EL device can be enhanced.

The positive type photosensitive resin composition used in the present invention can contain (D) a thermally crosslinking agent. The thermally crosslinking agent refers to a compound having at least two thermally reactive functional groups including an alkoxymethyl group, a methylol group, an epoxy group and an oxetanyl group in its molecule. It is preferred that the thermally crosslinking agent be contained therein because a resin of the (A) component or another additive component can be crosslinked to enhance the heat resistance, the chemical resistance and the hardness of the thermally cured film, and furthermore, the amount of the outgassed component from the cured film can be reduced to enhance the long-term reliability of the organic EL display device.

Preferred examples of a compound having at least two alkoxymethyl groups or methylol groups include DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, HMOM-TPHAP (hereinabove, trade names, available from Honshu Chemical Industry Co., Ltd.), NIKALAC (registered trademark) MX-290, NIKALACMX-280, NIKALACMX-270, NIKALAC MX-279, NIKALAC MW-100LM and NIKALAC MX-750LM (hereinabove, trade names, available from SANWA CHEMICAL CO., LTD.).

Preferred examples of a compound having at least two epoxy groups include Epolight40E, Epolight100E, Epolight200E, Epolight400E, Epolight70P, Epolight200P, Epolight400P, Epolight1500NP, Epolight80MF, Epolight4000, Epolight3002 (hereinabove, available from Kyoeisha Chemical Co., Ltd.), Denacol EX-212L, Denacol EX-214L, Denacol EX-216L, Denacol EX-850L (hereinabove, available from Nagase ChemteX Corporation), GAN, GOT (hereinabove, available from Nippon Kayaku Co., Ltd.), Epikote 828, Epikote 1002, Epikote 1750, Epikote 1007, YX8100-BH30, E1256, E4250, E4275 (hereinabove, available from Mitsubishi Chemical Corporation), EPICLON EXA-9583, HP4032 (hereinabove, available from DIC Corporation), VG3101 (available from Mitsui Chemicals, Inc.), TEPIC S, TEPIC G, TEPIC P (hereinabove, available from Nissan Chemical Industries, Ltd.), Denacol EX-321L (available from Nagase ChemteX Corporation), NC6000 (available from Nippon Kayaku Co., Ltd.), EPOTOHTO YH-434L (available from TOHTO Chemical Industry Co., Ltd.), EPPN502H, NC3000 (available from Nippon Kayaku Co., Ltd.), EPICLON N695, HP7200 (hereinabove, available from DIC Corporation), and the like.

Preferred examples of a compound having at least two oxetanyl groups include ETERNACOLL EHO, ETERNACOLL OXBP, ETERNACOLL OXTP, ETERNACOLL OXMA (hereinabove, available from Ube Industries, Ltd.), an oxetane derivative of phenol novolak, and the like.

Two or more kinds of the thermally crosslinking agents may be used in combination.

It is preferred that the content of the thermally crosslinking agent be greater than or equal to 1% by weight and less than or equal to 30% by weight relative to the whole amount of the resin composition excluding the solvent. When the content of the thermally crosslinking agent is greater than or equal to 1% by weight and less than or equal to 30% by weight, the chemical resistance and the hardness of the baked or cured film can be enhanced, furthermore, the amount of the outgassed component from the cured film can be reduced to enhance the long-term reliability of the organic EL display device, and the positive type photosensitive resin composition is also excellent in preservation stability.

The positive type photosensitive resin composition used in the present invention may contain an adhesion improving agent. Examples of the adhesion improving agent include silane coupling agents such as vinyltrimethoxysilane, vinyltriethoxysilane, epoxycyclohexylethyltrimethoxysilane, 3-glycidoxypropyltrimethoxysilane, 3-glycidoxypropyltriethoxysilane, p-styryltrimethoxysilane, 3-aminopropyltrimethoxysilane, 3-aminopropyltriethoxysilane and N-phenyl-3-aminopropyltrimethoxysilane, a titanium chelating agent, an aluminum chelating agent, a compound obtained by allowing an aromatic amine compound and an alkoxy group-containing silicon compound to react with each other, and the like. Two or more kinds thereof may be contained in the positive type photosensitive resin composition. By making the positive type photosensitive resin composition contain the adhesion improving agent, in the case of subjecting a photosensitive resin film to development or the like, the adhesion thereof to a silicon wafer or an underlying base material made of ITO, SiO₂, silicon nitride or the like can be enhanced. Moreover, the resistance against oxygen plasma, which is used for washing and the like, or a UV ozone treatment can be enhanced. It is preferred that the content of the adhesion improving agent be 0.1 to 10% by weight relative to the whole amount of the resin composition excluding the solvent.

For the purpose of enhancing the wettability to a substrate, the positive type photosensitive resin composition used in the present invention may contain a surfactant as necessary. A commercially available compound can be used as the surfactant, and specifically, examples of a silicone-based surfactant include a surfactant belonging to the SH series, SD series or ST series available from Dow Corning Toray Co., Ltd., the BYK series available from BYK Japan KK, the KP series available from Shin-Etsu Chemical Co., Ltd., the disk Home series available from NOF CORPORATION or the TSF series available from Momentive Performance Materials Inc., examples of a fluorine-based surfactant include a surfactant belonging to the “Megafac (registered trademark)” series available from DIC Corporation, the Fluorad series available from 3M Japan Limited, the “Surflon (registered trademark)” series or “Asahi Guard (registered trademark)” series available from ASAHI GLASS CO., LTD., the EF series available from Shin Akita Kasei KK or the PolyFox series available from OMNOVA Solutions, Inc., and examples of a surfactant composed of an acryl-based polymer and/or a methacryl-based polymer include a surfactant belonging to the POLYFLOW series available from Kyoeisha Chemical Co., Ltd. or the “DISPARLON (registered trademark)” series available from Kusumoto Chemicals, Ltd., but the surfactant is not limited thereto.

The content of the surfactant is preferably 0.001 to 1% by weight relative to the whole amount of the resin composition excluding the solvent.

For the purpose of making up for the alkali developability of the positive type photosensitive resin composition used in the present invention, the photosensitive resin composition may contain a compound having a phenolic hydroxyl group. Examples of the compound having a phenolic hydroxyl group include Bis-Z, BisOC-Z, BisOPP-Z, BisP-CP, Bis26X-Z, BisOTBP-Z, BisOCHP-Z, BisOCR-CP, BisP-MZ, BisP-EZ, Bis26X-CP, BisP-PZ, BisP-IPZ, BisCRIPZ, BisOCP-IPZ, BisOIPP-CP, Bis26X-IPZ, BisOTBP-CP, TekP-4HBPA (Tetrakis P-DO-BPA), TrisPHAP, TrisP-PA, TrisP-PHBA, TrisP-SA, TrisOCR-PA, BisOFP-Z, BisRS-2P, BisPG-26X, BisRS-3P, BisOC-OCHP, BisPC-OCHP, Bis25X-OCHP, Bis26X-OCHP, BisOCHP-OC, Bis236T-OCHP, Methylenetris-FR-CR, BisRS-26X, BisRS-OCHP (trade names, available from Honshu Chemical Industry Co., Ltd.), BIR-OC, BIP-PC, BIR-PC, BIR-PTBP, BIR-PCHP, BIP-BIOC-F, 4PC, BIR-BIPC-F, TEP-BIP-A (trade names, available from ASAHI YUKIZAI CORPORATION), 1,4-dihydroxynaphthalene, 1,5-dihydroxynaphthalene, 1,6-dihydroxynaphthalene, 1,7-dihydroxynaphthalene, 2,3-dihydroxynaphthalene, 2,6-dihydroxynaphthalene, 2,7-dihydroxynaphthalene, 2,4-dihydroxyquinoline, 2,6-dihydroxyquinoline, 2,3-dihydroxyquinoxaline, anthracene-1,2,10-triol, anthracene-1,8,9-triol, 8-quinolinol, and the like. By making the positive type photosensitive resin composition contain the compound having a phenolic hydroxyl group, since the resulting positive type photosensitive resin composition hardly dissolves in an alkali developing solution before exposure and easily dissolves in an alkali developing solution after being subjected to exposure, there is little reduction in film thickness by development and the development is made in a short period of time to be facilitated. As such, the sensitivity is easily enhanced.

The content of such a compound having a phenolic hydroxyl group is preferably greater than or equal to 1% by weight and less than or equal to 20% by weight relative to the whole amount of the resin composition excluding the solvent.

Moreover, the positive type photosensitive resin composition used in the present invention may contain inorganic particles. Preferred specific examples thereof include silicon oxide, titanium oxide, barium titanate, alumina, talc, and the like, but the particle is not limited thereto. The primary particle diameter of the inorganic particles is preferably less than or equal to 100 nm and more preferably less than or equal to 60 nm.

The content of the inorganic particles is preferably 5 to 90% by weight relative to the whole amount of the resin composition excluding the solvent.

The positive type photosensitive resin composition used in the present invention may contain a thermal acid generator without impairing the long-term reliability of the organic EL display device. The thermal acid generator generates an acid by heating to promote a crosslinking reaction of the (D) thermally crosslinking agent, and furthermore, in the case where the resin of the (A) component has an unclosed imide-ring structure or oxazole-ring structure, the thermal acid generator can promote cyclization thereof to further enhance the mechanical properties of the cured film.

The onset temperature of thermal decomposition of the thermal acid generator used in the present invention is preferably 50° C. to 270° C. and more preferably lower than or equal to 250° C. Moreover, when a thermal acid generator which does not generate an acid at the time of drying (prebaking: about 70 to 140° C.) after the positive type photosensitive resin composition of the present invention is coated on a substrate and generates an acid at the time of final heating (curing: about 100 to 400° C.) after the coating film is subjected to subsequent exposure and development to be patterned is selected, the thermal acid generator is preferred because a decrease in sensitivity on development can be suppressed.

It is preferred that the acid generated from the thermal acid generator used in the present invention be a strong acid, and for example, arylsulfonic acids such as p-toluenesulfonic acid and benzenesulfonic acid, alkylsulfonic acids such as methanesulfonic acid, ethanesulfonic acid, propanesulfonic acid and butanesulfonic acid, and haloalkylsulfonic acids such as trifluoromethyl sulfonic acid are preferred. Each of these is used as a salt such as an onium salt or as a covalent bond compound such as imide sulfonate. Two or more kinds thereof may be contained in the positive type photosensitive resin composition.

The content of the thermal acid generator used in the present invention is preferably greater than or equal to 0.01% by weight and more preferably greater than or equal to 0.1% by weight relative to the whole amount of the resin composition excluding the solvent. By making the positive type photosensitive resin composition contain the thermal acid generator in an amount greater than or equal to 0.01% by weight, since the crosslinking reaction and the cyclization of an unclosed structure of the resin are promoted, the mechanical properties and chemical resistance of the cured film can be further enhanced. Moreover, from the viewpoint of the long-term reliability of the organic EL display device, the content thereof is preferably less than or equal to 5% by weight, more preferably less than or equal to 3% by weight and further preferably less than or equal to 2% by weight.

The production method of the organic EL display device according to the present invention is a production method of an organic EL display device which is characterized as including the step of obtaining a cured film being formed on a first electrode with a positive type photosensitive resin composition containing (A) an alkali-soluble resin, (B) ano-quinonediazide compound and (C) an organic solvent and constituting an insulating layer. Moreover, it is preferred that the production method of the organic EL display device according to the present invention include the step of obtaining a cured film being formed on a driving circuit with a positive type photosensitive resin composition containing (A) an alkali-soluble resin, (B) an o-quinonediazide compound and (C) an organic solvent and constituting a flattening layer.

Next, the production method of a cured film using the positive type photosensitive resin composition of the present invention will be described in detail. The positive type photosensitive resin composition of the present invention is coated by a spin coating method, a slit coating method, a dip coating method, a spray coating method, a printing method or the like to obtain a coating film of the positive type photosensitive resin composition. Prior to the coating, a substrate on which the positive type photosensitive resin composition is coated may be previously subjected to a pretreatment with the above-described adhesion improving agent. For example, a method of treating the base material surface with a solution prepared by dissolving an adhesion improving agent in a content of 0.5 to 20% by weight in a solvent such as isopropanol, ethanol, methanol, water, tetrahydrofuran, propylene glycol monomethyl ether acetate, propylene glycol monomethyl ether, ethyl lactate and diethyl adipate is exemplified. Examples of the treating method for the base material surface include a method of spin-coating, slit die-coating, bar-coating, dip-coating, spray-coating, steaming or the like. After the coating, the coating film is subjected to a reduced pressure drying treatment as necessary, and then, subjected to a heat treatment for 1 minute to several hours within the range of 50° C. to 180° C. using a hot plate, an oven, infrared rays, or the like to obtain a photosensitive resin film.

Next, a method of forming a pattern from the photosensitive resin film obtained will be described. The surface of the photosensitive resin film is irradiated with actinic rays through a mask having a desired pattern. Examples of the actinic rays used for exposure include ultraviolet rays, visible light rays, electron rays, X rays, and the like, and in the present invention, it is preferred that i-line (365 nm), h-line (405 nm) or g-line (436 nm) emitted from a mercury lamp be used.

After the exposure, the exposed part is removed with a developing solution. As the developing solution, an aqueous solution of a compound exhibiting alkalinity such as tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine and hexamethylenediamine is preferred. Moreover, in some cases, these aqueous alkali solutions may be added with one prepared by using a polar solvent such as N-methyl-2-pyrrolidone, N,N-dimethylformamide, N,N-dimethylacetamide, dimethyl sulfoxide, gamma-butyrolactone and dimethylacrylamide; a kind of alcohol such as methanol, ethanol and isopropanol; a kind of ester such as ethyl lactate and propylene glycol monomethyl ether acetate; and a kind of ketone such as cyclopentanone, cyclohexanone, isobutyl ketone and methyl isobutyl ketone, singly or in combination of plural kinds thereof. As the developing system, the spray system, paddle system, immersion system, ultrasonic system, and the like can be adopted.

Next, it is preferred that the pattern formed by development be subjected to a rinsing treatment with distilled water. In this context, the distilled water may also be added with a kind of alcohol such as ethanol and isopropyl alcohol, a kind of ester such as propylene glycol monomethyl ether acetate and the like to perform a rinsing treatment.

Next, a heating treatment is performed. Since the residual solvent and components low in heat resistance can be removed by the heating treatment, the heat resistance and the chemical resistance can be enhanced. In particular, in the case where the positive type photosensitive resin composition of the present invention contains an alkali-soluble resin selected among a polyimide precursor and a polybenzoxazole precursor, an interpolymer thereof or an interpolymer of those and a polyimide, since the imide ring or the oxazole ring is formed by the heating treatment, the heat resistance and the chemical resistance can be enhanced, and moreover, in the case where the positive type photosensitive resin composition contains a compound having at least two alkoxymethyl groups, methylol groups, epoxy groups or oxetanyl groups, the thermally crosslinking reaction can be promoted by the heating treatment and the heat resistance and the chemical resistance can be enhanced. This heating treatment is performed for 5 minutes to 5 hours by setting predetermined temperature levels to gradually increase the temperature or setting a temperature range to continuously increase the temperature. In one case, the heat treatment is performed at 150° C. and 250° C. for 30 minutes each. Alternatively, examples thereof include a method of linearly increasing the temperature over a 2-hour period from room temperature to 300° C. With regard to the heating treatment condition in the present invention, the temperature preferably lies within the range of 150° C. to 400° C. and more preferably lies within the range of higher than or equal to 200° C. and lower than or equal to 350° C.

### EXAMPLES

Hereinafter, the present invention will be described with reference to examples and the like, but the present invention should not be limited by these examples. In this connection, the evaluation of a positive type photosensitive resin composition in EXAMPLES was performed by the following methods.

(1) Preparation of Film Subjected to Development for Sensitivity Evaluation

Using a coating/developing apparatus (coater developer) Mark-7 (available from Tokyo Electron Limited), a varnish was spin-coated on an 8-inch silicon wafer and baked for 3 minutes on a 120° C. hot plate to prepare a prebaked film with a film thickness of 3.0 m. Afterward, using an i-line stepper NSR-2005 i9C which is an exposure machine (available from NIKON CORPORATION), the prebaked film was subjected to exposure through a mask having a pattern of contact holes with a diameter of 10 μm at an exposure dose of 100 to 1200 mJ/cm² in 50 mJ/cm²-step increments. After the exposure, using the developing apparatus (developer) in Mark-7, the film was subjected to development over a period during which the reduction in film thickness on development becomes 0.5 μm using a 2.38% by weight aqueous tetramethylammonium solution (hereinafter TMAH, available from TAMA CHEMICALS CO., LTD.), after which the film was rinsed with distilled water and subjected to shake-off drying to obtain a pattern.

Measurement Method of Film Thickness

Using the Lambda Ace STM-602 available from SCREEN Holdings Co., Ltd., the film thickness was measured under the condition of the refractive index of 1.63.

Calculation of Sensitivity

Using the FDP microscope MX61 (available from Olympus Corporation), the pattern of a film subjected to development which is obtained by the above-mentioned method was observed at 20 magnifications, and the lowest required exposure quantity with which the opening diameter of the contact hole becomes 10 μm was determined to be defined as the sensitivity.

(2) Electron Probe Microanalyzer Measurement for Insulating Layer

Preparation method of organic EL display device A schematic illustration of a substrate used is shown in FIG. 2. First, among Reference Examples listed in Table 1, a varnish corresponding to each of Examples was coated on an alkali-free glass substrate 10 of 38×46 mm by a spin coating method and subjected to pre-baking for 2 minutes on a 120° C. hot plate. This film was subjected to UV exposure through a photomask, after which the film was subjected to development with a 2.38% aqueous TMAH solution to make only the exposed portion dissolve, and then, the film was rinsed with pure water. The obtained polyimide precursor pattern was cured for 60 minutes in a 250° C. oven under a nitrogen atmosphere. In this way, only on a substrate effective area, a flattening layer 11 was formed. The thickness of the flattening layer was determined to be about 2.0 μm. Next, an APC alloy film of 100 nm was formed on the whole face of the substrate by a sputtering method and etched to forma reflection electrode 12. Afterward, an ITO transparent conductive film of 10 nm was formed on the whole face of the substrate by a sputtering method and etched to form a first electrode 13. Moreover, for simultaneously taking out a second electrode, an auxiliary electrode 14 was also formed simultaneously therewith. The obtained substrate was subjected to ultrasonic washing with “Semico Clean 56” (trade name, available from Furuuchi Chemical Corporation) for 10 minutes, and then, the substrate was washed with ultrapure water. Next, among Reference Examples listed in Table 1, a varnish corresponding to each of Examples was coated on the whole face of this substrate by a spin coating method and subjected to pre-baking for 2 minutes on a 120° C. hot plate. This film was subjected to UV exposure through a photomask, after which the film was subjected to development with a 2.38% aqueous TMAH solution to make only the exposed portion dissolve, and then, the film was rinsed with pure water. The obtained polyimide precursor pattern was cured for 60 minutes in a 250° C. oven under a nitrogen atmosphere. In this way, openings with a width of 70 μm and a length of 260 μm were arranged at a 155-μm pitch in the width direction and a 465-μm pitch in the length direction, and an insulating layer 15, being composed of a photosensitive polyimide, having a shape in which the first electrode is exposed through respective openings was formed only on a substrate effective area. In this connection, finally, a light-emitting pixel is formed in each of the openings. Moreover, the substrate effective area was determined to be a square with a side of 16 mm, and the thickness of the insulating layer was determined to be about 2.0 μm.

Next, using the substrate on which the flattening layer, the reflection electrode, the first electrode and the insulating layer were formed, the preparation of an organic EL display device was performed. The substrate was subjected to a nitrogen plasma treatment as a pretreatment, after which an organic EL layer 16 containing a light-emitting layer was formed by a vacuum vapor deposition method. In this connection, the degree of vacuum on vapor deposition was less than or equal to 1×10⁻³ Pa, and during the vapor deposition, the substrate was rotated against the vapor deposition source. First, a layer of a compound (HT-1) of 10 nm as a hole injection layer and a layer of a compound (HT-2) of 50 nm as a hole transport layer were vapor deposited. Next, a compound (GH-1) as a host material and a compound (GD-1) as a dopant material were vapor deposited on the light-emitting layer so that the dope concentration becomes 10% and the resulting layer has a thickness of 40 nm. Next, a layer with a thickness of 40 nm which is composed of a compound (ET-1) and LiQ mixed at a volume ratio of 1:1 as the electron transport material was layered thereon. The structure of each of compounds used for the organic EL layer is as follows.

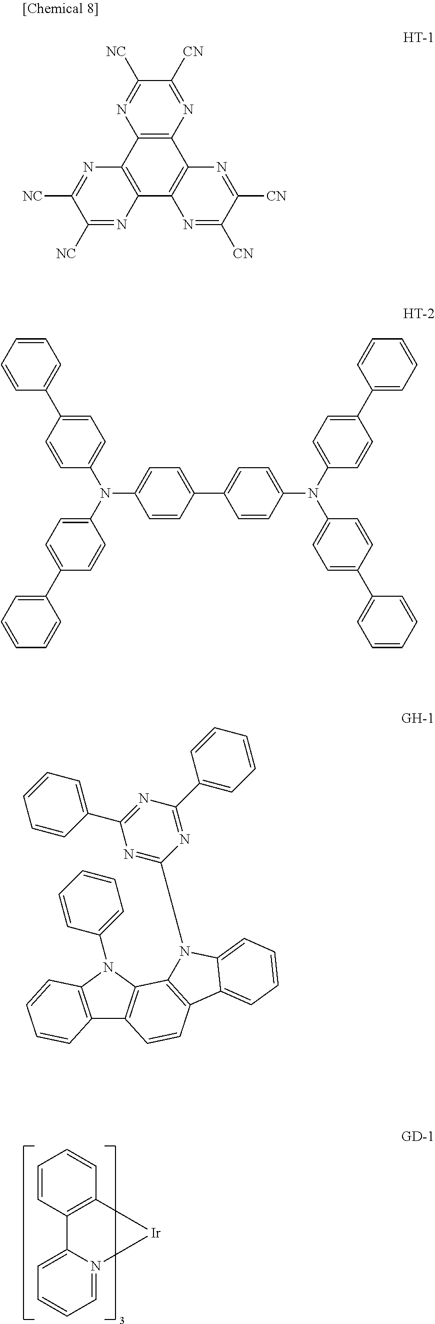

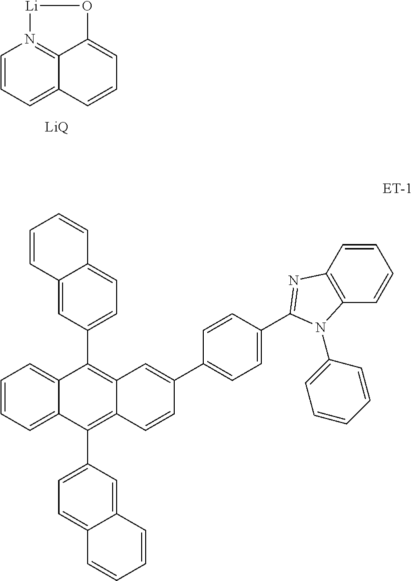

Next, a layer of LiQ of 2 nm was vapor deposited, after which a layer of 10 nm which is composed of Mg and Ag mixed at a volume ratio of 10:1 was vapor deposited to form a second electrode 17. Finally, under a low-humidity nitrogen atmosphere, sealing was performed by making a cap-like glass plate bond thereto with an epoxy resin-based adhesive, and four light-emitting devices having a square shape with a side of 5 mm were prepared on one piece of substrate. In this connection, this so-called film thickness refers to a value displayed on a crystal oscillation type film thickness monitor.

Electron Probe Microanalyzer Measurement

The cap-like glass plate of the organic EL display device prepared above was removed, and the insulating layer portion was exposed by oblique polishing and ion milling. The exposed portion was subjected to carbon shadowing, and then, a cured film was analyzed for the elemental analysis with an electron probe microanalyzer EMPA-1610 (available from SHIMADZU CORPORATION). Under the measurement conditions of the acceleration voltage: 15 kV, the beam size: 10 μm, the irradiation current: 10 nA and the measurement time: 10 seconds, with regard to C (elemental carbon), Kα peak intensity of 44.70 Å was measured using an LS12L dispersive crystal, and with regard to S (elemental sulfur), Kα peak intensity of 5.37 Å was measured using a PET dispersive crystal. As the standard sample, BaSO₄ was used, and samples were subjected to a ZAF correction (Z: atomic number correction, A: absorption correction, F: fluorescence excitation correction). Each sample was measured 3 times, and an average value thereof was determined to calculate the mole ratio S/C of sulfur to carbon.

(3) Electron Probe Microanalyzer Measurement for Flattening Layer

The cap-like glass plate of an organic EL display device prepared in the same manner as that for (2) was removed, and the flattening layer portion was exposed by oblique polishing and ion milling. Next, samples were measured in the same manner as that for (2) by means of an electron probe microanalyzer to calculate the mole ratio S/C of sulfur to carbon.

(4) Outgassing Measurement for Insulating Layer

The cap-like glass plate, the second electrode and the organic thin film layer of an organic EL display device prepared in the same manner as that for (2) were removed, and the insulating layer was exposed. A 10-mg portion of this insulating layer was subjected to adsorbing/capturing by a purge-and-trap method. Specifically, using helium as the purge gas, the collected cured film was heated for 30 minutes at 180° C. to make an adsorbent (Carbotrap 400) trap components desorbed therefrom.

The trapped components were thermally desorbed for 5 minutes at 280° C., and then, using the GC-MS apparatus 6890/5973N (available from Agilent Technologies), under the conditions of the column temperature: 40 to 300° C., the carrier gas: helium (1.5 mL/min) and the scanning range: m/z=29 to 600, the GC-MS analysis was performed. As the standard substance, n-hexadecane was adopted, the GC-MS analysis was performed in the same manner as above, and a calibration curve was prepared to calculate the amount of gas generated in terms of n-hexadecane.

A 10-mg portion of the obtained cured film was subjected to adsorbing/capturing by a purge-and-trap method. Specifically, using helium as the purge gas, the collected cured film was heated for 30 minutes at 180° C. to make an adsorbent (Carbotrap 400) trap components desorbed therefrom.

The trapped components were thermally desorbed for 5 minutes at 280° C., and then, using the GC-MS apparatus 6890/5973N (available from Agilent Technologies), under the conditions of the column temperature: 40 to 300° C., the carrier gas: helium (1.5 mL/min) and the scanning range: m/z 29 to 600, the GC-MS analysis was performed. As the standard substance, n-hexadecane was adopted, the GC-MS analysis was performed in the same manner as above, and a calibration curve was prepared to calculate the amount of gas generated in terms of n-hexadecane.

(5) Outgassing Measurement for Flattening Layer

The cap-like glass plate, the second electrode, the organic thin film layer, the insulating layer and the first electrode of an organic EL display device prepared in the same manner as that for (2) were removed, and the flattening layer was exposed. A 10-mg portion of this flattening layer was subjected to outgassing measurement in the same manner as that for (4).

(6) Thermal Weight Reduction Temperature Measurement for Insulating Layer

The cap-like glass plate, the second electrode and the organic thin film layer of an organic EL display device prepared in the same manner as that for (2) were removed, and the insulating layer was exposed. Using a thermogravimetric apparatus TGA-50 (available from SHIMADZU CORPORATION), a 10-mg portion of this insulating layer was pre-dried for 30 minutes at 150° C. under a nitrogen atmosphere, after which, during the temperature increasing process at a temperature increasing rate of 10° C./minute, the temperature at the point of time when the weight is reduced by 5% as compared with the initial weight was measured.

(7) Thermal Weight Reduction Temperature Measurement for Flattening Layer

The cap-like glass plate, the second electrode, the organic thin film layer, the insulating layer and the first electrode of an organic EL display device prepared in the same manner as that for (2) were removed, and the flattening layer was exposed. A 10-mg portion of this flattening layer was subjected to thermal weight reduction temperature measurement, and the temperature at the point of time when the weight is reduced by 5% as compared with the initial weight was measured.

(8) Long-Term Reliability Test for Organic EL Display Device

An organic EL display device prepared by the method of (2) was placed on a hot plate heated to 80° C. so that the light-emitting surface faces upward and irradiated with UV light with a wavelength of 365 nm at an illuminance of 0.6 mW/cm². At the end of each of 250 hours, 500 hours and 1000 hours, the device was made to emit light at a direct current drive mode of 10 mA/cm² to be measured for the light-emitting area of the light-emitting pixel.

### Synthesis Example 1 Synthesis of Hydroxyl Group-Containing Diamine Compound

In a mixture of 100 mL of acetone and 17.4 g (0.3 mol) of propylene oxide, 18.3 g (0.05 mol) of 2,2-bis(3-amino-4-hydroxyphenyl)hexafluoropropane (hereinbelow, referred to as BAHF) was dissolved, and the solution was cooled to −15° C. To this, a solution prepared by dissolving 20.4 g (0.11 mol) of 3-nitrobenzoyl chloride in 100 mL of acetone was added dropwise. After the completion of dropping, the contents were allowed to undergo a reaction for 4 hours at −15° C., and then, the temperature thereof was returned to room temperature. The precipitated white solid matter was filtered off and dried under vacuum at 50° C.

In a 300-mL stainless steel autoclave, 30 g of the solid matter was placed, the solid matter was dispersed in 250 mL of methyl cellosolve, and to this dispersion, 2 g of 5% palladium-carbon was added. Hydrogen was introduced thereinto by means of a balloon, and the contents were allowed to undergo a reductive reaction at room temperature. After about 2 hours, it was confirmed that the balloon no longer deflates, and the reaction was terminated. After the completion of the reaction, the contents were filtered to remove the palladium compound as the catalyst and were concentrated on a rotary evaporator to obtain a hydroxyl group-containing diamine compound represented by the following formula.

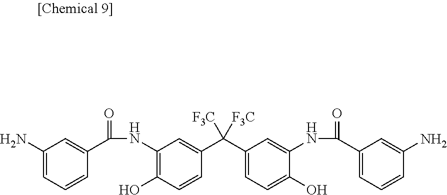 [SMILES: Nc1cccc(C(=O)Nc2cc(C(c3ccc(O)c(NC(=O)c4cccc(N)c4)c3)(C(F)(F)F)C(F)(F)F)ccc2O)c1]

### Synthesis Example 2 Synthesis of Alkali-Soluble Resin (A-1)

Under a stream of dry nitrogen, 31.0 g (0.10 mol) of 3,3′,4,4′-diphenyl ether tetracarboxylic acid dianhydride (hereinbelow, referred to as ODPA) was dissolved in 500 g of NMP. To this, 45.35 g (0.075 mol) of the hydroxyl group-containing diamine compound obtained in Synthesis Example 1 and 1.24 g (0.005 mol) of 1,3-bis(3-aminopropyl)tetramethyldisiloxane were added together with 50 g of NMP, the contents were allowed to undergo a reaction for 1 hour at 20° C. and then allowed to undergo a reaction for 2 hours at 50° C. Next, to the reaction liquid, 4.36 g (0.04 mol) of 4-aminophenol as a terminal blocking agent was added together with 5 g of NMP, and the contents were allowed to undergo a reaction for 2 hours at 50° C. Afterward, to the reaction liquid, a solution prepared by diluting 28.6 g (0.24 mol) of N,N-dimethylformamide dimethylacetal with 50 g of NMP was added dropwise over a period of 10 minutes. After dropping, the contents were stirred for 3 hours at 50° C. After the completion of stirring, the solution was cooled to room temperature, and then, the solution was charged into 3 L of water to obtain a white precipitate. The precipitate was collected by filtration to be washed three times with water, after which the precipitate was dried for 24 hours by means of a vacuum drying machine at 80° C. to obtain a polyimide precursor (A-1) which is an aimed alkali-soluble resin.

### Synthesis Example 3 Synthesis of Alkali-Soluble Resin (A-2)

Under a stream of dry nitrogen, 29.3 g (0.08 mol) of BAHF, 1.24 g (0.005 mol) of 1,3-bis(3-aminopropyl)tetramethyldisiloxane and 3.27 g (0.03 mol) of 3-aminophenol as a terminal blocking agent were dissolved in 150 g of N-methyl-2-pyrrolidone (NMP). To this, 31.0 g (0.1 mol) of ODPA was added together with 50 g of NMP, and the contents were stirred for 1 hour at 20° C. and then stirred for 4 hours at 50° C. Afterward, 15 g of xylene was added thereto, and the contents were stirred for 5 hours at 150° C. while water was azeotropically removed together with xylene. After the completion of stirring, the solution was charged into 3 L of water to collect a white precipitate. The precipitate was collected by filtration to be washed three times with water, after which the precipitate was dried for 24 hours by means of a vacuum drying machine at 80° C. to obtain a polyimide (A-2) which is an alkali-soluble resin.

### Synthesis Example 4 Synthesis of Alkali-Soluble Resin (A-3)

Under a stream of dry nitrogen, in a mixture of 50 g of NMP and 26.4 g (0.3 mol) of glycidylmethyl ether, 18.3 g (0.05 mol) of BAHF was dissolved, and the temperature of the solution was lowered to −15° C. To this, a solution prepared by dissolving 7.4 g (0.025 mol) of diphenyl etherdicarboxylic acid dichloride (available from NIHON NOHYAKU CO., LTD.) and 5.1 g (0.025 mol) of isophthalic acid chloride (available from Tokyo Chemical Industry Co., Ltd.) in 25 g of γ-butyrolactone (GBL) was added dropwise so that the temperature of the contents does not exceed 0° C. After the completion of dropping, stirring was continued for 6 hours at −15° C. After the completion of the reaction, the solution was charged into 3 L of 10% by weight aqueous methanol to collect a white precipitate. The precipitate was collected by filtration to be washed three times with water, after which the precipitate was dried for 24 hours by means of a vacuum drying machine at 80° C. to obtain a polybenzoxazole precursor (A-3) which is an aimed alkali-soluble resin.

### Synthesis Example 5 Synthesis of Alkali-Soluble Resin Solution (A-4)

In a 500-ml flask, 5 g of 2,2′-azobis(isobutyronitrile), 5 g of t-dodecanethiol and 150 g of propylene glycol monomethyl ether acetate (hereinafter, abbreviated as PGMEA) were placed. Afterward, 30 g of methacrylic acid, 35 g of benzyl methacrylate and 35 g of tricyclo[5.2.1.0^{2,6}]decane-8-yl methacrylate were added thereto, the contents were stirred for a while at room temperature, and the inside of the flask was replaced with nitrogen, after which the contents were stirred with heating for 5 hours at 70° C. Next, to the obtained solution, 15 g of glycidyl methacrylate, 1 g of dimethylbenzylamine and 0.2 g of p-methoxyphenol were added, and the contents were stirred with heating for 4 hours at 90° C. to obtain an acrylic resin solution (A-4). The solid content of the obtained acrylic resin solution (A-4) was determined to be 43% by weight.

### Synthesis Example 6 Synthesis of Alkali-Soluble Resin (A-5)

A polyimide (A-5) which is an alkali-soluble resin containing a sulfur atom in its skeleton was obtained in the same manner as that in Synthesis Example 3 except that 15.5 g (0.05 mol) of ODPA and 17.9 g (0.05 mol) of 3,3′,4,4′-diphenyl sulfone tetracarboxylic acid dianhydride were added as the acid dianhydride.

### Synthesis Example 7 Synthesis of Quinonediazide Compound (B-1)

Under a stream of dry nitrogen, 21.22 g (0.05 mol) of TrisP-PA (trade name, available from HONSHU CHEMICAL INDUSTRY CO., LTD.) and 36.27 g (0.135 mol) of 5-naphthoquinonediazide sulfonyl chloride were dissolved in 450 g of 1,4-dioxane, and the solution was allowed to stand at room temperature. To this, a mixture of 50 g of 1,4-dioxane and 15.18 g of triethylamine was added dropwise so that the temperature of the system does not become 35° C. or higher. After dropping, the contents were stirred for 2 hours at 30° C. The triethylamine salt was filtered off and the filtrate was charged into water. Afterward, the separated-out precipitate was collected by filtration. The precipitate was dried by means of a vacuum drying machine to obtain a quinonediazide compound (B-1) represented by the following formula.

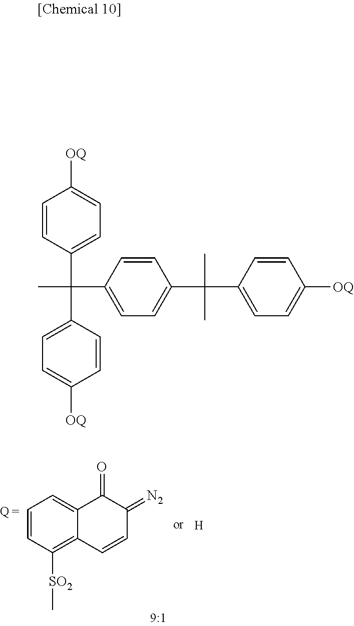

### Synthesis Example 8 Synthesis of Quinonediazide Compound (B-2)

Under a stream of dry nitrogen, 21.22 g (0.05 mol) of TrisP-PA (trade name, available from HONSHU CHEMICAL INDUSTRY CO., LTD.) and 36.27 g (0.135 mol) of 4-naphthoquinonediazide sulfonyl chloride were dissolved in 450 g of 1,4-dioxane, and the solution was allowed to stand at room temperature. To this, a mixture of 50 g of 1,4-dioxane and 15.18 g of triethylamine was added dropwise so that the temperature of the system does not become 35° C. or higher. After dropping, the contents were stirred for 2 hours at 30° C. The triethylamine salt was filtered off and the filtrate was charged into water. Afterward, the separated-out precipitate was collected by filtration. The precipitate was dried by means of a vacuum drying machine to obtain a quinonediazide compound (B-2) represented by the following formula.

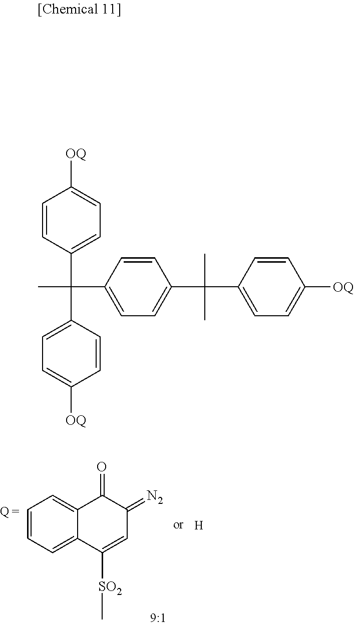

### Synthesis Example 9 Synthesis of Quinonediazide Compound (B-3)

Under a stream of dry nitrogen, 21.22 g (0.05 mol) of TrisP-PA (trade name, available from HONSHU CHEMICAL INDUSTRY CO., LTD.) and 36.27 g (0.10 mol) of 5-naphthoquinonediazide sulfonyl chloride were dissolved in 450 g of 1,4-dioxane, and the solution was allowed to stand at room temperature. To this, a mixture of 50 g of 1,4-dioxane and 15.18 g of triethylamine was added dropwise so that the temperature of the system does not become 35° C. or higher. After dropping, the contents were stirred for 2 hours at 30° C. The triethylamine salt was filtered off and the filtrate was charged into water. Afterward, the separated-out precipitate was collected by filtration. The precipitate was dried by means of a vacuum drying machine to obtain a quinonediazide compound (B-3) represented by the following formula.

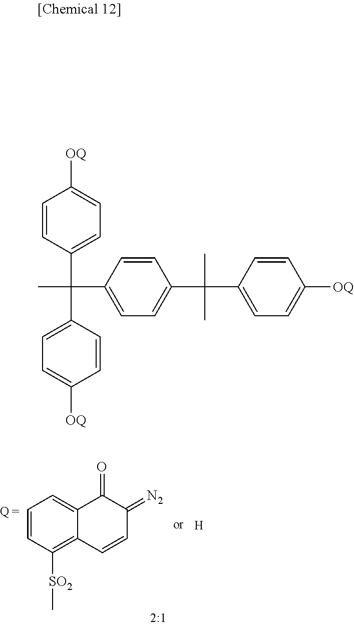

### Reference Example 1

In a mixed solvent of 32.0 g of propylene glycol monomethyl ether (hereinafter, referred to as PGME) and 8.0 g of γ-butyrolactone (hereinafter, referred to as GBL), 10.0 g of an alkali-soluble resin (A-1) obtained in Synthesis Example 2 described above and 1.2 g of (B-1) were dissolved, after which the solution was filtered through a polytetrafluoroethylene-made filter of 0.2 μm (available from Sumitomo Electric Industries, Ltd.) to obtain a positive type photosensitive resin composition (Varnish) A.

### Reference Examples 2 to 31

Varnishes B to X and Varnishes a to h were obtained in the same manner as that in Reference Example 1 except that the kind of a compound and the amount thereof were set to those listed in Tables 1 and 2. In this connection, the name and structure of each of compounds shown in Table 1 are as follows.

D-1: HMOM-TPHAP (trade name, available from HONSHU CHEMICAL INDUSTRY CO., LTD.)

D-2: NC6000 (trade name, available from Nippon Kayaku Co., Ltd.)

E-1: PAG-103 (trade name, available from Ciba Japan K.K.)

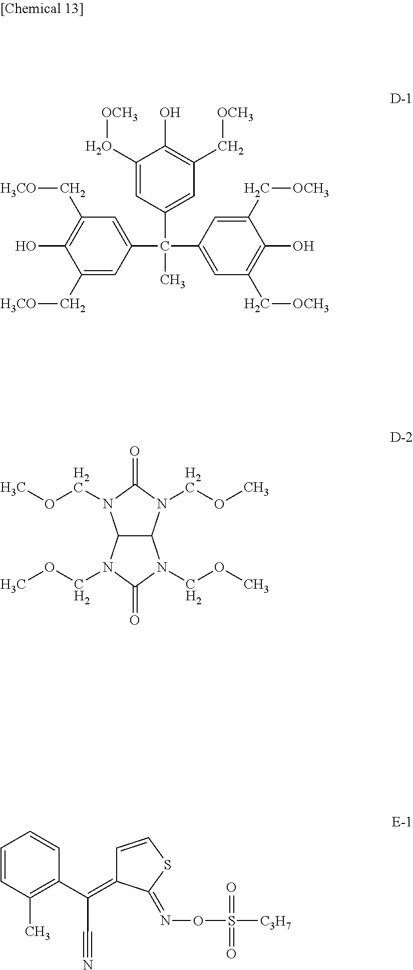

### Examples 1 to 24, Comparative Examples 1 to 8

The Varnish a was used for the flattening layer, each of Varnishes listed in Table 1 was used for the insulating layer, and an organic EL display device was prepared according to the method described above. This organic EL display device was used to perform the electron probe microanalyzer measurement for the insulating layer, the outgassing measurement for the insulating layer, the thermal weight reduction temperature measurement for the insulating layer, and the long-term reliability test for the organic EL display device, according to the methods described above. The evaluation results are shown in Tables 3 and 4.

### Examples 25 to 33

Two Varnishes listed in Table 1 were used for the flattening layer and the insulating layer respectively, and an organic EL display device was prepared according to the method described above. This organic EL display device was used to perform the electron probe microanalyzer measurement for the insulating layer and the flattening layer, the outgassing measurement for the insulating layer and the flattening layer, the thermal weight reduction temperature measurement for the insulating layer and the flattening layer, and the long-term reliability test for the organic EL display device, according to the methods described above. The evaluation results are shown in Table 5.

Test Result for Long-Term Reliability of Organic EL Display Device

With regard to devices in Examples 1 to 24 being organic EL display devices in which the insulating layer is constituted of a cured film obtained from a positive type photosensitive resin composition containing (A) an alkali-soluble resin, (B) an o-quinonediazide compound and (C) an organic solvent and the mole ratio S/C of sulfur to carbon obtained when being measured by means of an electron probe microanalyzer satisfies the requirement of being greater than or equal to 0.003 and less than or equal to 0.008, as compared with devices in Comparative Examples 1 to 8 which do not satisfy the above-mentioned conditions, extremely satisfactory results on the long-term reliability were obtained. In this connection, in Comparative Example 3, the long-term reliability test failed to be performed because there was an undissolved residue on the exposed part even at an exposure dose of 1200 mJ/cm² and a desired pattern failed to be obtained. In Comparative Example 3, the insulating layer was not subjected to patterning to prepare an organic EL display device, and the electron probe microanalyzer measurement, the outgassing measurement and the thermal weight reduction temperature measurement were performed according to the methods described above.

Furthermore, with regard to devices in Examples 25 to 27, 29, 31 and 33 being organic EL display devices in which, in addition to the insulating layer, the flattening layer is also constituted of a cured film obtained from a positive type photosensitive resin composition containing (A) an alkali-soluble resin, (B) an o-quinonediazide compound and (C) an organic solvent and the mole ratio S/C of sulfur to carbon obtained when being measured by means of an electron probe microanalyzer is greater than or equal to 0.003 and less than or equal to 0.008, further satisfactory results on the long-term reliability were obtained.

TABLE 1

| | Photosensitive | (A) | (B) | | (D) Thermally | |
|---|---|---|---|---|---|---|
| | resin | Alkali-soluble | o-Quinonediazide | | crosslinking | (E) Thermal acid |
| | composition | resin | compound | (C) Solvent | agent | generator |
| Reference | A | A-1 | B-1 | PGME/GBL | | |
| Example 1 | | 10.0 g | 1.2 g | 32.0 g/8.0 g | | |
| Reference | B | A-1 | B-1 | PGME/GBL | | |
| Example 2 | | 10.0 g | 1.0 g | 32.0 g/8.0 g | | |
| Reference | C | A-1 | B-1 | PGME/GBL | | |
| Example 3 | | 10.0 g | 0.8 g | 32.0 g/8.0 g | | |
| Reference | D | A-1 | B-1 | PGME/GBL | | |
| Example 4 | | 10.0 g | 0.6 g | 32.0 g/8.0 g | | |
| Reference | E | A-1 | B-1 | PGME/GBL | | |
| Example 5 | | 10.0 g | 0.4 g | 32.0 g/8.0 g | | |
| Reference | F | A-1 | B-1 | PGME/GBL | | |
| Example 6 | | 10.0 g | 1.2 g | 25.0 g/15.0 g | | |
| Reference | G | A-1 | B-1 | PGME/GBL | | |
| Example 7 | | 10.0 g | 1.2 g | 36.0 g/4.0 g | | |
| Reference | H | A-1 | B-1 | PGME/PGMEA | | |
| Example 8 | | 10.0 g | 1.2 g | 32.0 g/8.0 g | | |
| Reference | I | A-1 | B-1 | GBL | | |
| Example 9 | | 10.0 g | 1.2 g | 40.0 g | | |
| Reference | J | A-1 | B-1 | PGME/GBL | | E-1 |
| Example 10 | | 10.0 g | 1.0 g | 32.0 g/8.0 g | | 0.2 g |
| Reference | K | A-1 | B-2 | PGME/GBL | | |
| Example 11 | | 10.0 g | 1.2 g | 32.0 g/8.0 g | | |
| Reference | L | A-1 | B-2 | PGME/GBL | | |
| Example 12 | | 10.0 g | 1.0 g | 32.0 g/8.0 g | | |
| Reference | M | A-1 | B-3 | PGME/GBL | | |
| Example 13 | | 10.0 g | 1.2 g | 32.0 g/8.0 g | | |
| Reference | N | A-1 | B-1 | PGME/GBL | D-1 | |
| Example 14 | | 10.0 g | 1.2 g | 32.0 g/8.0 g | 1.5 g | |
| Reference | O | A-1 | B-1 | PGME/GBL | D-2 | |
| Example 15 | | 10.0 g | 1.2 g | 32.0 g/8.0 g | 1.5 g | |
| Reference | P | A-2 | B-1 | PGME/GBL | | |
| Example 16 | | 10.0 g | 1.2 g | 32.0 g/8.0 g | | |

TABLE 2

| | Photosensitive | (A) | (B) | | (D) Thermally | |
|---|---|---|---|---|---|---|
| | resin | Alkali-soluble | o-Quinonediazide | | crosslinking | (E) Thermal acid |
| | composition | resin | compound | (C) Solvent | agent | generator |
| Reference | Q | A-2 | B-1 | PGME/GBL | | |
| Example 17 | | 10.0 g | 0.8 g | 32.0 g/8.0 g | | |
| Reference | R | A-2 | B-1 | PGME/GBL | D-1 | |
| Example 18 | | 10.0 g | 1.2 g | 32.0 g/8.0 g | 1.5 g | |
| Reference | S | A-3 | B-1 | PGME/GBL | | |
| Example 19 | | 10.0 g | 1.2 g | 32.0 g/8.0 g | | |
| Reference | T | A-3 | B-1 | PGME/GBL | | |
| Example 20 | | 10.0 g | 0.8 g | 32.0 g/8.0 g | | |
| Reference | U | A-3 | B-1 | PGME/GBL | D-1 | |
| Example 21 | | 10.0 g | 1.2 g | 32.0 g/8.0 g | 1.5 g | |
| Reference | V | A-4 | B-1 | PGMEA/GBL | | |
| Example 22 | | 23.3 g | 1.2 g | 18.7 g/8.0 g | | |
| Reference | W | A-4 | B-1 | PGMEA/GBL | | |
| Example 23 | | 23.3 g | 0.8 g | 18.7 g/8.0 g | | |
| Reference | X | A-4 | B-1 | PGMEA/GBL | D-1 | |
| Example 24 | | 23.3 g | 1.2 g | 18.7 g/8.0 g | 1.5 g | |
| Reference | a | A-1 | B-1 | PGME/GBL | | |
| Example 25 | | 10.0 g | 1.5 g | 32.0 g/8.0 g | | |
| Reference | b | A-1 | B-1 | PGME/GBL | D-1 | |
| Example 26 | | 10.0 g | 2.0 g | 32.0 g/8.0 g | 1.5 g | |
| Reference | c | A-1 | B-1 | PGME/GBL | | |
| Example 27 | | 10.0 g | 0.2 g | 32.0 g/8.0 g | | |
| Reference | d | A-1 | B-1 | PGME/GBL | | E-1 |
| Example 28 | | 10.0 g | 1.0 g | 32.0 g/8.0 g | | 0.6 g |
| Reference | e | A-2 | B-1 | PGME/GBL | | |
| Example 29 | | 10.0 g | 1.5 g | 32.0 g/8.0 g | | |
| Reference | f | A-3 | B-1 | PGME/GBL | | |
| Example 30 | | 10.0 g | 1.5 g | 32.0 g/8.0 g | | |
| Reference | g | A-4 | B-1 | PGME/GBL | | |
| Example 31 | | 10.0 g | 1.5 g | 32.0 g/8.0 g | | |
| Reference | h | A-5 | B-1 | PGME/GBL | | |
| Example 32 | | 10.0 g | 1.2 g | 32.0 g/8.0 g | | |

TABLE 3

| | | | | Cured film characteristics of insulating layer | | | | Organic EL device | | |
|---|---|---|---|---|---|---|---|---|---|---|
| | Photosensitive resin | | | | | | Sum of | long-term reliability | | |
| | composition | | Photosensitive | | 5% Weight | | amounts of | Pixel light-emitting | | |
| | Flattening | Insulating | characteristics | S/C | reduction | Outgassed | outgassed | area [%] | | |
| | layer | layer | Sensitivity | ratio | temperature | components | components | 250 hr | 500 hr | 1000 hr |
| Example 1 | a | A | 150 mJ/cm² | 0.008 | 330° C. | PGME = 1 ppm | 7 ppm | 100 | 95 | 80 |
| | | | | | | GBL = 6 ppm | | | | |
| Example 2 | a | B | 200 mJ/cm² | 0.006 | 333° C. | PGME = 1 ppm | 7 ppm | 100 | 100 | 85 |
| | | | | | | GBL = 6 ppm | | | | |
| Example 3 | a | C | 250 mJ/cm² | 0.005 | 338° C. | PGME = 1 ppm | 7 ppm | 100 | 100 | 95 |
| | | | | | | GBL = 6 ppm | | | | |
| Example 4 | a | D | 400 mJ/cm² | 0.004 | 345° C. | PGME = 1 ppm | 6 ppm | 100 | 100 | 100 |
| | | | | | | GBL = 5 ppm | | | | |
| Example 5 | a | E | 700 mJ/cm² | 0.003 | 346° C. | PGME = 1 ppm | 6 ppm | 100 | 100 | 100 |
| | | | | | | GBL = 5 ppm | | | | |
| Example 6 | a | F | 150 mJ/cm² | 0.008 | 330° C. | PGME = 1 ppm | 10 ppm | 100 | 90 | 75 |
| | | | | | | GBL = 9 ppm | | | | |
| Example 7 | a | G | 150 mJ/cm² | 0.008 | 330° C. | PGME = 1 ppm | 4 ppm | 100 | 100 | 85 |
| | | | | | | GBL = 3 ppm | | | | |
| Example 8 | a | H | 150 mJ/cm² | 0.008 | 330° C. | PGME = 1 ppm | 2 ppm | 100 | 100 | 90 |
| | | | | | | PGMEA = 1 ppm | | | | |
| Example 9 | a | I | 250 mJ/cm² | 0.008 | 328° C. | GBL = 23 ppm | 23 ppm | 100 | 85 | 55 |
| Example 10 | a | J | 200 mJ/cm² | 0.008 | 340° C. | PGME = 1 ppm | 7 ppm | 100 | 95 | 80 |
| | | | | | | GBL = 6 ppm | | | | |
| Example 11 | a | K | 120 mJ/cm² | 0.005 | 328° C. | PGME = 1 ppm | 7 ppm | 100 | 100 | 95 |
| | | | | | | GBL = 6 ppm | | | | |
| Example 12 | a | L | 180 mJ/cm² | 0.004 | 326° C. | PGME = 1 ppm | 7 ppm | 100 | 100 | 100 |
| | | | | | | GBL = 6 ppm | | | | |
| Example 13 | a | M | 200 mJ/cm² | 0.006 | 333° C. | PGME = 1 ppm | 7 ppm | 100 | 100 | 95 |
| | | | | | | GBL = 6 ppm | | | | |
| Example 14 | a | N | 150 mJ/cm² | 0.006 | 373° C. | PGME = 1 ppm | 5 ppm | 100 | 100 | 90 |
| | | | | | | GBL = 4 ppm | | | | |
| Example 15 | a | O | 200 mJ/cm² | 0.006 | 366° C. | PGME = 1 ppm | 5 ppm | 100 | 100 | 90 |
| | | | | | | GBL = 4 ppm | | | | |
| Example 16 | a | P | 250 mJ/cm² | 0.008 | 340° C. | PGME = 1 ppm | 6 ppm | 100 | 95 | 80 |
| | | | | | | GBL = 5 ppm | | | | |

TABLE 4

| | | | | Cured film characteristics of insulating layer | | | | Organic EL device | | |
|---|---|---|---|---|---|---|---|---|---|---|
| | Photosensitive resin | | | | | | Sum of | long-term reliability | | |
| | composition | | Photosensitive | | 5% Weight | | amounts of | Pixel light-emitting | | |
| | Flattening | Insulating | characteristics | S/C | reduction | Outgassed | outgassed | area [%] | | |
| | layer | layer | Sensitivity | ratio | temperature | components | components | 250 hr | 500 hr | 1000 hr |
| Example 17 | a | P | 450 mJ/cm² | 0.005 | 342° C. | PGME = 1 ppm | 7 ppm | 100 | 100 | 95 |
| | | | | | | GBL = 6 ppm | | | | |
| Example 18 | a | Q | 300 mJ/cm² | 0.006 | 375° C. | PGME = 1 ppm | 5 ppm | 100 | 100 | 90 |
| | | | | | | GBL = 4 ppm | | | | |
| Example 19 | a | R | 200 mJ/cm² | 0.008 | 321° C. | PGME = 1 ppm | 8 ppm | 100 | 95 | 80 |
| | | | | | | GBL = 7 ppm | | | | |
| Example 20 | a | S | 300 mJ/cm² | 0.005 | 322° C. | PGME = 1 ppm | 8 ppm | 100 | 100 | 95 |
| | | | | | | GBL = 7 ppm | | | | |
| Example 21 | a | T | 200 mJ/cm² | 0.006 | 360° C. | PGME = 1 ppm | 6 ppm | 100 | 100 | 90 |
| | | | | | | GBL = 5 ppm | | | | |
| Example 22 | a | U | 600 mJ/cm² | 0.008 | 310° C. | PGMEA = 2 ppm | 9 ppm | 100 | 85 | 75 |
| | | | | | | GBL = 7 ppm | | | | |
| Example 23 | a | V | 900 mJ/cm² | 0.005 | 312° C. | PGMEA = 2 ppm | 9 ppm | 100 | 90 | 80 |
| | | | | | | GBL = 7 ppm | | | | |
| Example 24 | a | W | 700 mJ/cm² | 0.006 | 330° C. | PGMEA = 2 ppm | 9 ppm | 100 | 90 | 80 |
| | | | | | | GBL = 7 ppm | | | | |
| Comparative | a | a | 150 mJ/cm² | 0.010 | 325° C. | PGME = 1 ppm | 8 ppm | 100 | 75 | 20 |
| Example 1 | | | | | | GBL = 7 ppm | | | | |
| Comparative | a | b | 150 mJ/cm² | 0.012 | 365° C. | PGME = 1 ppm | 7 ppm | 80 | 60 | 0 |
| Example 2 | | | | | | GBL = 6 ppm | | | | |
| Comparative | a | c | Impossible to | 0.001 | 336° C. | PGME = 1 ppm | 6 ppm | Impossible to evaluate | | |
| Example 3 | | | process | | | GBL = 5 ppm | | | | |
| Comparative | a | d | 150 mJ/cm² | 0.012 | 365° C. | PGME = 1 ppm | 7 ppm | 80 | 60 | 0 |
| Example 4 | | | | | | GBL = 6 ppm | | | | |
| Comparative | a | e | 150 mJ/cm² | 0.009 | 343° C. | PGME = 1 ppm | 7 ppm | 100 | 75 | 30 |
| Example 5 | | | | | | GBL = 6 ppm | | | | |
| Comparative | a | f | 250 mJ/cm² | 0.009 | 320° C. | PGME = 1 ppm | 7 ppm | 100 | 75 | 20 |
| Example 6 | | | | | | GBL = 6 ppm | | | | |
| Comparative | a | g | 500 mJ/cm² | 0.010 | 308° C. | PGME = 1 ppm | 7 ppm | 100 | 65 | 0 |
| Example 7 | | | | | | GBL = 6 ppm | | | | |
| Comparative | a | h | 400 mJ/cm² | 0.014 | 325° C. | PGME = 1 ppm | 7 ppm | 100 | 80 | 40 |
| Example 8 | | | | | | GBL = 6 ppm | | | | |

TABLE 5

| | Photo- | | Cured film characteristics | | | | | | | | | | |
|---|---|---|---|---|---|---|---|---|---|---|---|---|---|
| | sensitive | | of insulating layer | | | | | | | | | | |
| | resin | | | 5% | | Sum of | Cured film characteristics | | | | | | |
| | composition | | | Weight | | amounts | of flattening layer | | | | Organic EL device | | |
| | Flat- | | | reduc- | | of | | | | Sum of | long-term reliability | | |
| | ten- | Insu- | | tion | Outgassed | outgassed | | 5% Weight | | amounts of | Pixel light-emitting | | |
| | ing | lating | S/C | temper- | com- | com- | S/C | reduction | Outgassed | outgassed | area [%] | | |
| | layer | layer | ratio | ature | ponents | ponents | ratio | temperature | components | components | 250 hr | 500 hr | 1000 hr |
| Example 1 | a | A | 0.008 | 330° C. | PGME = | 7 ppm | 0.010 | 328° C. | PGME = 1 ppm | 7 ppm | 100 | 95 | 80 |
| | | | | | 1 ppm | | | | GBL = 6 ppm | | | | |
| Example | A | A | | | GBL = | | 0.008 | 330° C. | PGME = 1 ppm | 7 ppm | 100 | 100 | 90 |
| 25 | | | | | 6 ppm | | | | GBL = 6 ppm | | | | |
| Example | B | A | | | | | 0.006 | 336° C. | PGME = 1 ppm | 7 ppm | 100 | 100 | 95 |
| 26 | | | | | | | | | GBL = 6 ppm | | | | |
| Example | C | A | | | | | 0.005 | 340° C. | PGME = 1 ppm | 7 ppm | 100 | 100 | 100 |
| 27 | | | | | | | | | GBL = 6 ppm | | | | |
| Example | e | A | | | | | 0.009 | 346° C. | PGME = 1 ppm | 7 ppm | 100 | 95 | 80 |
| 28 | | | | | | | | | GBL = 6 ppm | | | | |
| Example | P | A | | | | | 0.005 | 342° C. | PGME = 1 ppm | 7 ppm | 100 | 100 | 90 |
| 29 | | | | | | | | | GBL = 6 ppm | | | | |
| Example | f | A | | | | | 0.009 | 320° C. | PGME = 1 ppm | 7 ppm | 100 | 95 | 80 |
| 30 | | | | | | | | | GBL = 6 ppm | | | | |
| Example | s | A | | | | | 0.005 | 322° C. | PGME = 1 ppm | 8 ppm | 100 | 100 | 90 |
| 31 | | | | | | | | | GBL = 7 ppm | | | | |
| Example | g | A | | | | | 0.010 | 308° C. | PGMEA = 1 ppm | 7 ppm | 100 | 85 | 75 |
| 32 | | | | | | | | | GBL = 6 ppm | | | | |
| Example | U | A | | | | | 0.005 | 312° C. | PGMEA = 1 ppm | 8 ppm | 100 | 95 | 85 |
| 33 | | | | | | | | | GBL = 7 ppm | | | | |

### DESCRIPTION OF REFERENCE SIGNS

1: TFT (thin film transistor)
2: Wiring
3: TFT insulating layer
4: Flattening layer
5: ITO (transparent electrode)
6: Substrate
7: Contact hole
8: Insulating layer
10: Glass substrate
11: Flattening layer
12: Reflection electrode
13: First electrode
14: Auxiliary electrode
15: Insulating layer
16: Organic EL layer
17: Second electrode

1. An organic EL display device, comprising an insulating layer formed on a first electrode of the organic EL display device and constituted of a cured film obtained from a positive type photosensitive resin composition containing (A) an alkali-soluble resin, (B) an o-quinonediazide compound and (C) an organic solvent,
wherein the mole ratio S/C of sulfur to carbon obtained when a section of the cured film is measured by means of an electron probe microanalyzer is greater than or equal to 0.003 and less than or equal to 0.008.

2. The organic EL display device according to claim 1, wherein the (A) alkali-soluble resin contained in the positive type photosensitive resin composition is constituted of at least one or more kind of alkali-soluble resin selected among a polyimide, a polyimide precursor and a polybenzoxazole precursor or an interpolymer thereof.

3. The organic EL display device according to claim 1, wherein the total amount of gas components derived from the organic solvent among components adsorbed and captured by a purge-and-trap method and detected by gas chromatography-mass spectrometry (GC-MS) in outgassed components emitted when a cured film constituting the insulating layer is heated at 180° C. for 30 minutes is less than or equal to 10 ppm in terms of n-hexadecane.

4. The organic EL display device according to claim 1, wherein the 5% thermal weight reduction temperature of a cured film constituting the insulating layer is higher than or equal to 350° C.

5. The organic EL display device according to claim 1, further comprising a flattening layer formed on a driving circuit of the organic EL display device and constituted of a cured film obtained from a positive type photosensitive resin composition containing (A) an alkali-soluble resin, (B) an o-quinonediazide compound and (C) an organic solvent,
wherein the mole ratio S/C of sulfur to carbon obtained when a section of the cured film is measured by means of an electron probe microanalyzer is greater than or equal to 0.003 and less than or equal to 0.008.

6. The organic EL display device according to claim 5, wherein the (A) alkali-soluble resin contained in the positive type photosensitive resin composition is constituted of at least one or more kind of alkali-soluble resin selected among a polyimide, a polyimide precursor and a polybenzoxazole precursor or an interpolymer thereof.

7. The organic EL display device according to claim 5, wherein the total amount of gas components derived from the organic solvent among components adsorbed and captured by a purge-and-trap method and detected by gas chromatography-mass spectrometry (GC-MS) in outgassed components emitted when a cured film constituting the flattening layer is heated at 180° C. for 30 minutes is less than or equal to 10 ppm in terms of n-hexadecane.

8. The organic EL display device according to claim 5, wherein the 5% thermal weight reduction temperature of a cured film constituting the flattening layer is higher than or equal to 350° C.

9. The organic EL display device according to claim 2, wherein the total amount of gas components derived from the organic solvent among components adsorbed and captured by a purge-and-trap method and detected by gas chromatography-mass spectrometry (GC-MS) in outgassed components emitted when a cured film constituting the insulating layer is heated at 180° C. for 30 minutes is less than or equal to 10 ppm in terms of n-hexadecane.

10. The organic EL display device according to claim 2, wherein the 5% thermal weight reduction temperature of a cured film constituting the insulating layer is higher than or equal to 350° C.

11. The organic EL display device according to claim 3, wherein the 5% thermal weight reduction temperature of a cured film constituting the insulating layer is higher than or equal to 350° C.

12. The organic EL display device according to claim 2, further comprising a flattening layer formed on a driving circuit of the organic EL display device and constituted of a cured film obtained from a positive type photosensitive resin composition containing (A) an alkali-soluble resin, (B) an o-quinonediazide compound and (C) an organic solvent,
wherein the mole ratio S/C of sulfur to carbon obtained when a section of the cured film is measured by means of an electron probe microanalyzer is greater than or equal to 0.003 and less than or equal to 0.008.

13. The organic EL display device according to claim 3, further comprising a flattening layer formed on a driving circuit of the organic EL display device and constituted of a cured film obtained from a positive type photosensitive resin composition containing (A) an alkali-soluble resin, (B) an o-quinonediazide compound and (C) an organic solvent,
wherein the mole ratio S/C of sulfur to carbon obtained when a section of the cured film is measured by means of an electron probe microanalyzer is greater than or equal to 0.003 and less than or equal to 0.008.

14. The organic EL display device according to claim 4, further comprising a flattening layer formed on a driving circuit of the organic EL display device and constituted of a cured film obtained from a positive type photosensitive resin composition containing (A) an alkali-soluble resin, (B) an o-quinonediazide compound and (C) an organic solvent,
wherein the mole ratio S/C of sulfur to carbon obtained when a section of the cured film is measured by means of an electron probe microanalyzer is greater than or equal to 0.003 and less than or equal to 0.008.

15. The organic EL display device according to claim 6, wherein the total amount of gas components derived from the organic solvent among components adsorbed and captured by a purge-and-trap method and detected by gas chromatography-mass spectrometry (GC-MS) in outgassed components emitted when a cured film constituting the flattening layer is heated at 180° C. for 30 minutes is less than or equal to 10 ppm in terms of n-hexadecane.

16. The organic EL display device according to claim 6, wherein the 5% thermal weight reduction temperature of a cured film constituting the flattening layer is higher than or equal to 350° C.

17. The organic EL display device according to claim 7, wherein the 5% thermal weight reduction temperature of a cured film constituting the flattening layer is higher than or equal to 350° C.
